(19) United States
(12) Patent Application Publication
(10) Pub. No.: US 2009/0267047 A1
(43) Pub. Date: Oct. 29, 2009

(54) SEMICONDUCTOR MEMORY DEVICE AND MANUFACTURING METHOD THEREOF

(75) Inventors: Yoshitaka SASAGO, Tachikawa (JP); Riichiro TAKEMURA, Tokyo (JP); Masaharu KINOSHITA, Kokubunji (JP); Toshiyuki MINE, Fussa (JP); Akio SHIMA, Hino (JP); Hideyuki MATSUOKA, Nishitokyo (JP); Mutsuko HATANO, Kokubunji (JP); Norikatsu TAKAURA, Tokyo (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/430,539

(22) Filed: Apr. 27, 2009

(30) Foreign Application Priority Data
Apr. 28, 2008 (JP) 2008-117055

(51) Int. Cl. H01L 47/00

(52) U.S. Cl. 257/4; 438/486; 257/E47.001; 257/E47.005

(57) ABSTRACT

The present invention can promote the large capacity, high performance and high reliability of a semiconductor memory device by realizing high-performance of both the semiconductor device and a memory device when the semiconductor memory device is manufactured by stacking a memory device such as ReRAM or the phase change memory and the semiconductor device. After a polysilicon forming a selection device is deposited in an amorphous state at a low temperature, the crystallization of the polysilicon and the activation of impurities are briefly performed with heat treatment by laser annealing. When laser annealing is performed, the recording material located below the silicon subjected to the crystallization is completely covered with a metal film or with the metal film and an insulating film, thereby making it possible to suppress a temperature increase at the time of performing the annealing and to reduce the thermal load of the recording material.

### CLAIM OF PRIORITY

The present application claims priority from Japanese patent application JP 2008-117055, filed on Apr. 28, 2008, the content of which is hereby incorporated by reference into this application.

### BACKGROUND OF THE INVENTION

1. Field of the Invention

The present invention relates to a semiconductor integrated circuit device and a method of manufacturing the same, and more particularly, to a technology that can realize high integration and high performance of an electrically rewritable nonvolatile semiconductor memory device.

2. Description of the Related Art

Among electrically rewritable nonvolatile semiconductor memory devices, a so-called flash memory, which can be batch erased, has been known. Recently, a demand for a flash memory as a memory device for small, portable information devices such as a portable personal computer, a digital still camera, and the like, has rapidly increased because it has excellent portability and high impact resistance, while being able to be electrically batch erased. A critical factor to expand the market of the flash memory is the reduction of bit cost by reducing an area of a memory cell. In order to achieve this, a variety of memory cell methods have been proposed.

An example of a so-called NAND type flash memory, which is a kind of a contactless type cell suitable for manufacturing a large capacity memory is disclosed in “Symp. On VLSI Technology, 2007, p. 12-13” and “International Electron Devices Meeting, 2004, p. 873-876”. The reduction in a physical area of the memory cell to approximately 4 F² (F: minimum processed dimension) has been successful by using the structures described in the reference documents. A large capacity NAND type flash memory can be realized by reducing the minimum processed dimension and making the minimum processed dimension multi-valued using the cell of 4 F², such that a market of the NAND type flash memory as a memory for data storage has rapidly expanded. However, since an operating voltage of the flash memory cannot be reduced, defect in the flash memory easily occurs due to an inter-electrode dielectric breakdown, etc. in respects to the miniaturization of the flash memory. As a result, it is considered that it is difficult to manufacture the product of F<32 nm.

Therefore, after the generation of 32 nm, a need exists for a memory for data storage that can replace the flash memory. Lowering cost, which is most important problem of the memory for data storage, can be realized by three-dimensionally configuring the memory. For example, a three-dimensional phase change memory technology using a transistor as a selection device is disclosed in U.S. Pat. No. 7,251,157. Even if the transistor can be used as the selection device as described above, it is the most preferable from the viewpoint of miniaturization of the cell to use a memory array where a diode is used as the selection device and a serial structure of the diode and a variable resistance element is arranged in a cross point type. As the variable resistance element, ReRAM materials such as NiO, CuO, and TiO₂ (each is disclosed in “Appl. Phys. Lett. 88, 202102 (2006)”, “International Electron Devices Meeting, 2006, S30 p. 6”, and “SSDM 2006 p. 4-14L”) are known in addition to the phase change memory.

As the variable resistance element, for example, the phase change memory device is preferable since it is excellent in terms of frequency of rewriting, retention characteristic, operating speed, and the like. However, there are problems in that the phase change material has a low melting point and when it is exposed to a high temperature of the melting point or more for a long time, the characteristics thereof are deteriorated due to a sublimation of a part of elements, and the like.

On the other hand, a transistor, a diode, and the like using semiconductor materials such as polysilicon cannot obtain sufficient characteristics if the crystallization of the semiconductor material and the activation of impurities is not subjected to a high-temperature annealing. As a result, there is a problem in that a process of manufacturing a stacked cross point type cell using the phase change device and the diode should achieve both (1) the crystallization of the materials for the transistor and diode, the activation of the impurities, and the performance improvement by annealing and (2) the prevention of the degradation in characteristics of the phase change materials due to a thermal load.

When recording materials including ReRAM, such as NiO, CuO, and TiO₂, which are not limited to the phase change materials, are heated to deposition temperature and crystallization temperature of the polysilicon, the quality thereof is changed, and the characteristics thereof are deteriorated.

### SUMMARY OF THE INVENTION

It is an object of the present invention to provide a technology for promoting high integration and high performance of a semiconductor memory device by reducing a thermal load to a variable resistance element and suppressing deterioration in the characteristics, in a process of manufacturing a memory where a semiconductor device using a polysilicon material and the variable resistance element are stacked. The above and other objects and new features will be clearly understood from the description of the specification and the accompanying drawings enclosed therein.

The exemplified invention disclosed in the subject application will be briefly described below.

In other words, according to the present invention, a method of manufacturing a semiconductor memory device having a structure where semiconductor devices including silicon materials and recording materials such as phase change materials or ReRAM materials are stacked includes: (1) depositing the recording materials on a semiconductor substrate; (2) depositing a metal film to cover an entire surface of the semiconductor substrate on which the recording materials are deposited; (3) depositing an amorphous silicon forming the semiconductor device on the metal film; and (4) crystallizing the amorphous silicon by annealing in a short time.

Further, according to the present invention, a method of manufacturing a semiconductor memory device having a structure where an array of a memory cell including silicon materials forming semiconductor devices or a recording material such as phase change materials or ReRAM materials are stacked includes: (A) depositing the recording materials on a semiconductor substrate; (B) depositing an insulating film to cover the entire surface of the semiconductor substrate on which the recording materials are deposited; (C) depositing the metal film to cover the entire surface of the insulating film; (D) depositing an amorphous silicon forming a diode on the metal film; and (E) crystallizing the amorphous silicon quickly by annealing in a short time.

Moreover, according to the present invention, a semiconductor memory device includes: an insulating film that is formed on a semiconductor substrate; plural first metal lines that are formed on the insulating film; plural diodes that are formed on each of the plural first metal lines; first electrodes that are formed on the each of the plural diodes; a recording material, such as phase change materials or ReRAM materials that are formed on the first electrodes; second electrodes that are formed on the phase change materials; and plural second metal lines that are formed the second electrodes, wherein the first metal line is made of metal having thermal conductivity higher than that of the second electrode interposed between the recording material and the second metal line.

The effect obtained according to the exemplified invention disclosed in the subject application will be briefly described below. The present invention can provide a large capacity, high performance, and high reliability nonvolatile semiconductor memory device by realizing the high performance and high reliability of both the variable resistance element and the selection device that are three-dimensionally stacked.

### BRIEF DESCRIPTION OF THE DRAWINGS

FIG. 1 is a partial plan view showing one example of a semiconductor memory device according to first to sixth embodiments of the present invention;

FIG. 2 is a partial cross-sectional view showing one example of a semiconductor memory device according to a first embodiment of the present invention (cross-sectional view taken along the line A-A of FIG. 1);

FIG. 3 is a partial cross-sectional view showing one example of the semiconductor memory device according to the first embodiment of the present invention (cross-sectional view taken along the line B-B of FIG. 1);

FIG. 4 is a partial cross-sectional view showing one example of the semiconductor memory device according to the first embodiment of the present invention (cross-sectional view taken along the line C-C of FIG. 1);

FIG. 5 is a partial cross-sectional view showing one example of the semiconductor memory device according to the first embodiment of the present invention (cross-sectional view taken along the line D-D of FIG. 1);

FIG. 6 is a partial cubic diagram showing one example of the semiconductor memory device according to the first embodiment of the present invention;

FIG. 7 is a diagram showing a time change of temperature in a set/reset operation of a phase change memory;

FIG. 8 is a circuit diagram showing a voltage condition in a reading operation of the semiconductor memory device according to the first embodiment of the present invention;

FIG. 9 is a circuit diagram showing a voltage condition in a set/reset operation of the semiconductor memory device according to the first embodiment of the present invention;

FIGS. 10A to 10C are partial cross-sectional views showing one example of a method of manufacturing a semiconductor memory device according to the first embodiment;

FIGS. 11A and 11B are partial cross-sectional views showing one example of the method of manufacturing a semiconductor memory device according to the first embodiment;

FIGS. 12A to 12D are partial cross-sectional views showing one example of the method of manufacturing a semiconductor memory device according to the first embodiment;

FIGS. 13A to 13D are partial cross-sectional views showing one example of the method of manufacturing a semiconductor memory device according to the first embodiment;

FIGS. 14A to 14C are partial cross-sectional views showing one example of the method of manufacturing a semiconductor memory device according to the first embodiment;

FIGS. 15A to 15C are partial cross-sectional views showing one example of the method of manufacturing a semiconductor memory device according to the first embodiment;

FIGS. 16A and 16B are partial cross-sectional views showing one example of the method of manufacturing a semiconductor memory device according to the first embodiment;

FIG. 17 is a partial plane view showing one example of the method of manufacturing a semiconductor memory device according to the first embodiment;

FIG. 18 is a partial cubic diagram showing one example of the method of manufacturing a semiconductor memory device according to the first embodiment;

FIGS. 19A and 19B are partial cross-sectional views showing one example of the method of manufacturing a semiconductor memory device according to the first embodiment;

FIGS. 20A and 20B are partial cross-sectional views showing one example of the method of manufacturing a semiconductor memory device according to the first embodiment;

FIGS. 21A and 21B are partial cross-sectional views showing one example of the method of manufacturing a semiconductor memory device according to the first embodiment;

FIGS. 22A to 22D are partial cross-sectional views showing one example of the method of manufacturing a semiconductor memory device according to the first embodiment;

FIGS. 23A to 23D are partial cross-sectional views showing one example of the method of manufacturing a semiconductor memory device according to the first embodiment;

FIGS. 24A to 24C are partial cross-sectional views showing one example of the method of manufacturing a semiconductor memory device according to the first embodiment;

FIGS. 25A to 25C are partial cross-sectional views showing one example of the method of manufacturing a semiconductor memory device according to the first embodiment;

FIGS. 26A and 26B are partial cross-sectional views showing one example of the method of manufacturing a semiconductor memory device according to the first embodiment;

FIG. 27 is a partial plane view showing one example of the method of manufacturing a semiconductor memory device according to the first embodiment;

FIGS. 28A and 28B are partial cubic diagrams showing one example of the method of manufacturing a semiconductor memory device according to the first embodiment;

FIGS. 29A and 29B are partial cross-sectional views showing one example of the method of manufacturing a semiconductor memory device according to the first embodiment;

FIG. 30 is a partial cubic diagram showing one example of the method of manufacturing a semiconductor memory device according to the first embodiment;

FIG. 31 is a partial cubic diagram showing one example of the method of manufacturing a semiconductor memory device according to the first embodiment;

FIG. 32 is a partial cubic diagram showing one example of the method of manufacturing a semiconductor memory device according to the first embodiment;

FIG. 33 is a partial cubic diagram showing one example of the method of manufacturing a semiconductor memory device according to the first embodiment;

FIG. 34 is a partial cubic diagram showing one example of the method of manufacturing a semiconductor memory device according to the first embodiment;

FIG. 35 is a partial cubic diagram showing one example of the method of manufacturing a semiconductor memory device according to the first embodiment;

FIGS. 36A and 36B are diagrams showing an effect of the method of manufacturing a semiconductor memory device according to the first embodiment;

FIG. 37A is a partial plane view showing one example of a method of manufacturing a semiconductor memory device according to a second embodiment; and FIGS. 37B and 37C are partial cross-sectional views showing one example of the method of manufacturing a semiconductor memory device according to the second embodiment;

FIGS. 38A and 38B are partial cross-sectional views showing one example of the method of manufacturing a semiconductor memory device according to the second embodiment;

FIGS. 39A and 39B are partial cross-sectional views showing one example of the method of manufacturing a semiconductor memory device according to the second embodiment;

FIGS. 40A and 40B are partial cross-sectional views showing one example of the method of manufacturing a semiconductor memory device according to the second embodiment;

FIGS. 41A and 41B are partial plan views showing one example of the method of manufacturing a semiconductor memory device according to the second embodiment;

FIG. 42 is a partial cross-sectional view showing one example of the method of manufacturing a semiconductor memory device according to the second embodiment;

FIGS. 43A and 43B are partial cross-sectional views showing one example of the method of manufacturing a semiconductor memory device according to the second embodiment;

FIGS. 44A and 44B are partial cross-sectional views showing one example of the method of manufacturing a semiconductor memory device according to the second embodiment;

FIGS. 45A and 45B are partial cross-sectional views showing one example of the method of manufacturing a semiconductor memory device according to the second embodiment;

FIGS. 46A and 46B are partial cross-sectional views showing one example of the method of manufacturing a semiconductor memory device according to the second embodiment;

FIGS. 47A and 47B are partial cross-sectional views showing one example of a method of manufacturing a semiconductor memory device according to a third embodiment;

FIGS. 48A and 48B are partial cross-sectional views showing one example of the method of manufacturing a semiconductor memory device according to the third embodiment;

FIGS. 49A and 49B are partial cross-sectional views showing one example of the method of manufacturing a semiconductor memory device according to the third embodiment;

FIGS. 50A and 50B are partial cross-sectional views showing one example of the method of manufacturing a semiconductor memory device according to the third embodiment;

FIGS. 51A and 51B are partial cross-sectional views showing one example of the method of manufacturing a semiconductor memory device according to the third embodiment;

FIGS. 52A and 52B are partial cross-sectional views showing one example of the method of manufacturing a semiconductor memory device according to the third embodiment;

FIGS. 53A and 53B are partial cross-sectional views showing one example of the method of manufacturing a semiconductor memory device according to the third embodiment;

FIGS. 54A and 54B are partial cross-sectional views showing one example of the method of manufacturing a semiconductor memory device according to the third embodiment;

FIGS. 55A and 55B are partial cross-sectional views showing one example of the method of manufacturing a semiconductor memory device according to the third embodiment;

FIGS. 56A and 56B are partial cross-sectional views showing one example of the method of manufacturing a semiconductor memory device according to the third embodiment;

FIGS. 57A and 57B are partial cross-sectional views showing one example of the method of manufacturing a semiconductor memory device according to the third embodiment;

FIGS. 58A to 58C are partial cubic diagrams showing one example of the method of manufacturing a semiconductor memory device according to the third embodiment;

FIGS. 59A to 59C are partial cubic diagrams showing one example of the method of manufacturing a semiconductor memory device according to the third embodiment;

FIGS. 60A and 60B are partial cubic diagrams showing one example of the method of manufacturing a semiconductor memory device according to the third embodiment;

FIGS. 61A and 61B are partial cubic diagrams showing one example of the method of manufacturing a semiconductor memory device according to the third embodiment;

FIG. 62 is a partial cross-sectional view showing one example of a semiconductor memory device according to a fourth embodiment (cross-sectional view taken along the line A-A of FIG. 1);

FIG. 63 is a partial cross-sectional view showing one example of the semiconductor memory device according to the fourth embodiment (cross-sectional view taken along the line B-B of FIG. 1);

FIG. 64 is a partial cross-sectional view showing one example of the semiconductor memory device according to the fourth embodiment (cross-sectional view taken along the line C-C of FIG. 1);

FIG. 65 is a partial cross-sectional view showing one example of a semiconductor memory device according to the fourth embodiment (cross-sectional view taken along the line D-D of FIG. 1);

FIG. 66 is a partial cubic diagram showing two examples of the semiconductor memory device according to the fourth embodiment;

FIGS. 67A to 67C are partial cross-sectional views showing one example of the method of manufacturing a semiconductor memory device according to the fourth embodiment;

FIGS. 68A and 68B are partial cross-sectional views showing one example of the method of manufacturing a semiconductor memory device according to the fourth embodiment;

FIG. 69 is a partial cubic diagram showing one example of the method of manufacturing a semiconductor memory device according to the fourth embodiment;

FIGS. 70A and 70B are partial cubic diagrams showing one example of the method of manufacturing a semiconductor memory device according to the fourth embodiment;

FIGS. 71A and 71B are partial cross-sectional views showing one example of the method of manufacturing a semiconductor memory device according to the fourth embodiment;

FIGS. 72A and 72B are partial cross-sectional views showing one example of the method of manufacturing a semiconductor memory device according to the fourth embodiment;

FIG. 73 is a partial cubic diagram showing one example of the method of manufacturing a semiconductor memory device according to the fourth embodiment;

FIG. 74 is a partial cubic diagram showing one example of the method of manufacturing a semiconductor memory device according to the fourth embodiment;

FIGS. 75A to 75D are partial cross-sectional views showing one example of a method of manufacturing a semiconductor memory device according to a fifth embodiment;

FIGS. 76A to 76D are partial cross-sectional views showing one example of the method of manufacturing a semiconductor memory device according to the fifth embodiment;

FIGS. 77A to 77D are partial cross-sectional views showing one example of the method of manufacturing a semiconductor memory device according to the fifth embodiment; and

FIGS. 78A to 78D are partial cross-sectional views showing one example of the method of manufacturing a semiconductor memory device according to the fifth embodiment.

### DETAILED DESCRIPTION OF THE PREFERRED EMBODIMENTS

Hereinafter, exemplary embodiments of the present invention will be described with reference to the accompanying drawings. Further, like reference numerals refer to components having like functions throughout the drawings for explaining the exemplary embodiments, and the description thereof will not be repeated.

### First Embodiment

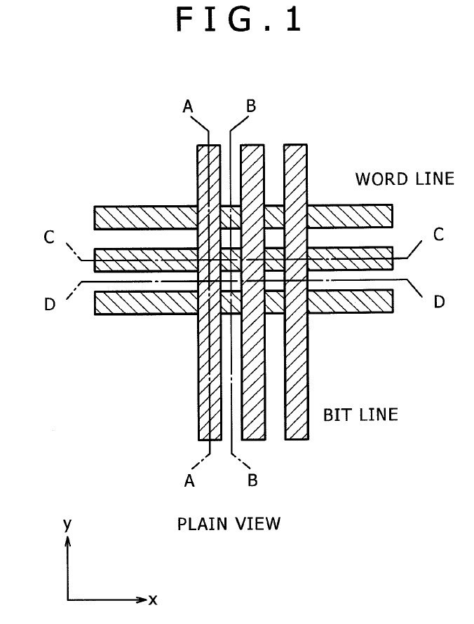

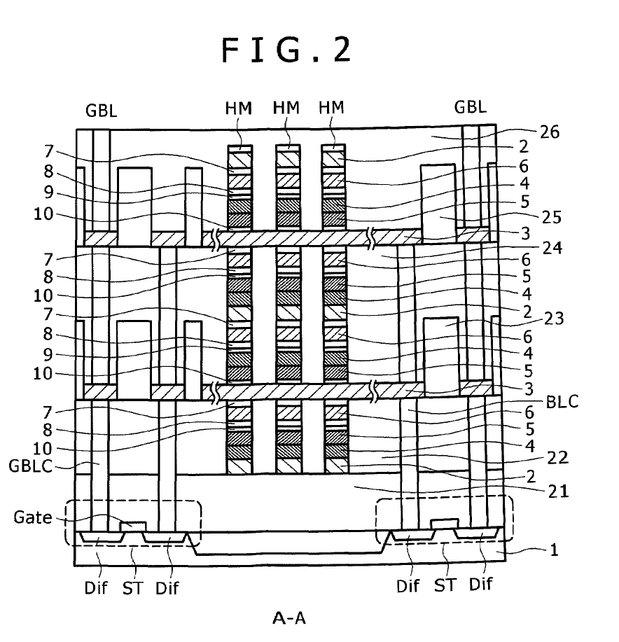

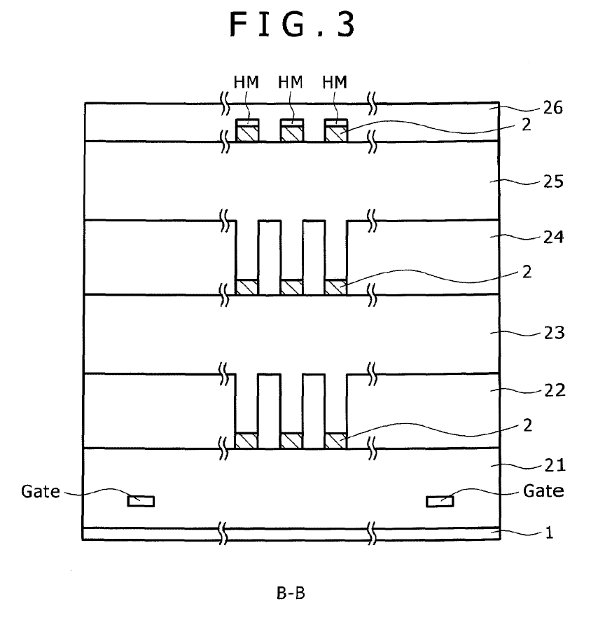

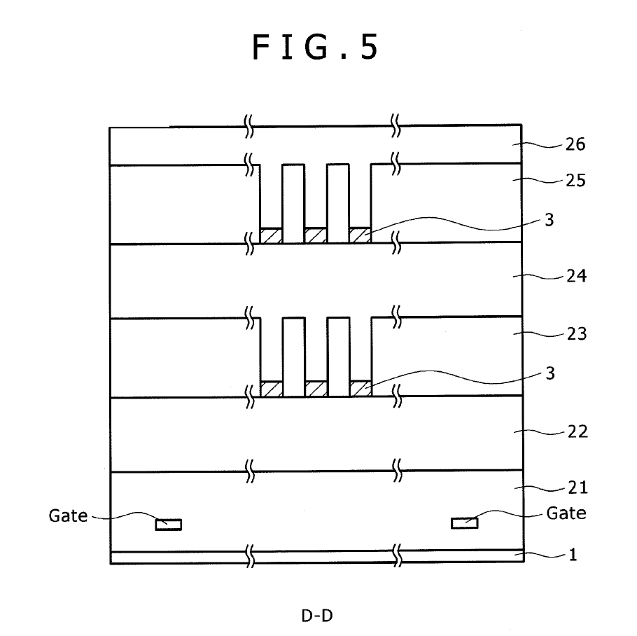

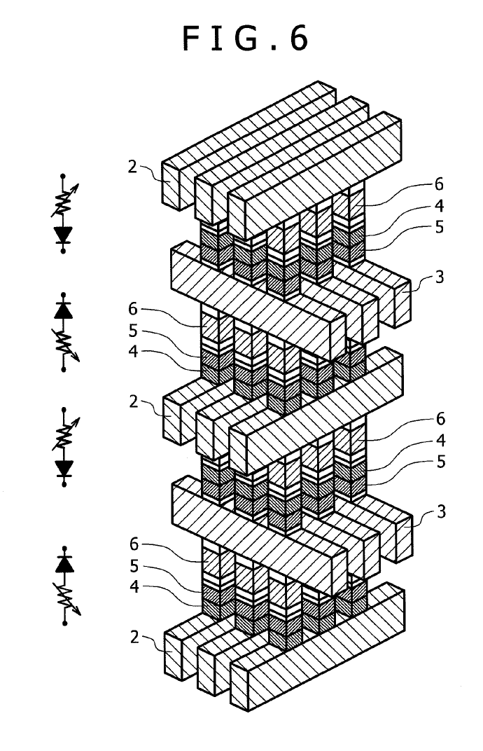

FIG. 1 is a partial plan view showing one example of a semiconductor memory device according to a first embodiment of the present invention and each of FIGS. 2 to 5 is a cross-sectional view taken along the line A-A, line B-B, line C-C, and line D-D in FIG. 1. Further, FIG. 6 is a cubic diagram showing a portion of a memory array. Moreover, in the plane view of FIG. 1 and the cubic diagram of FIG. 6, a portion of components is omitted to make the drawings easy to see.

The semiconductor memory device of the first embodiment uses a variable resistance element (for example, a phase change memory) as a memory element and a polysilicon diode as a selection device, wherein these form an array in a stacked cross point type. A word line extends in an X direction and a bit line extends in a y direction, inside a main plane of the semiconductor. Each line is connected to a diffusion layer of a selection transistor ST via a contact hole of an array end. The other diffusion layer of the selection transistor is connected to a global word line GWL and a global bit line GBL via the contact hole. An adjacent memory layer has a structure that commonly uses either one of the bit line and the word line. In order to realize this, the word line and polarity of a diode, which becomes a selection device, is a reverse direction at the adjacent memory layer (see FIG. 6). Even if FIGS. 1 to 6 show a memory array in the case where four layers are stacked, it is of course possible to stack five layers or more.

The phase change memory memories information by using a fact that phase change materials, such as Ge₂Sb₂Te₅, have a different resistance value in an amorphous state and a crystal state. The resistance is high in the amorphous state and the resistance is low in the crystal state. Therefore, the reading can be performed by providing a potential difference across the element to measure a current flowing in the element and discriminating the high resistance state/low resistance state of the element.

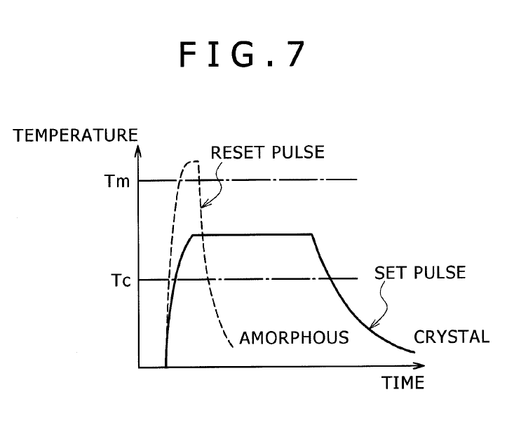

The operation of changing the phase change material from an amorphous state having the high resistance to a crystal state having the low resistance or vice versa, and the operation of changing the phase change material from the crystal state of the low resistance to an amorphous state having the high resistance are performed by providing the temperature change to the phase change material as shown in FIG. 7. The phase change material in the amorphous state is heated to a crystallization temperature or more for 10⁻⁶ seconds or more, such that it can enter the crystal state. Moreover, the phase change material in the crystal state is heated to a temperature of a melting point or more, such that it enters a liquid state. Thereafter, the material in the liquid state is rapidly cooled, such that it can enter the amorphous state.

The phase change memory performs data writing by changing the electric resistance of the phase change film into a different state according to Joule heat generated by a current. The reset operation, that is, the operation of changing into the amorphous state having high resistance is conducted by supplying a large amount of current in a short time to dissolve the phase change material and then, rapidly decreasing a current to rapidly cool it. On the other hand, the set operation, that is, the operation of changing into the crystal state having low resistance is conducted by supplying enough current to maintain the crystallization temperature over a long time.

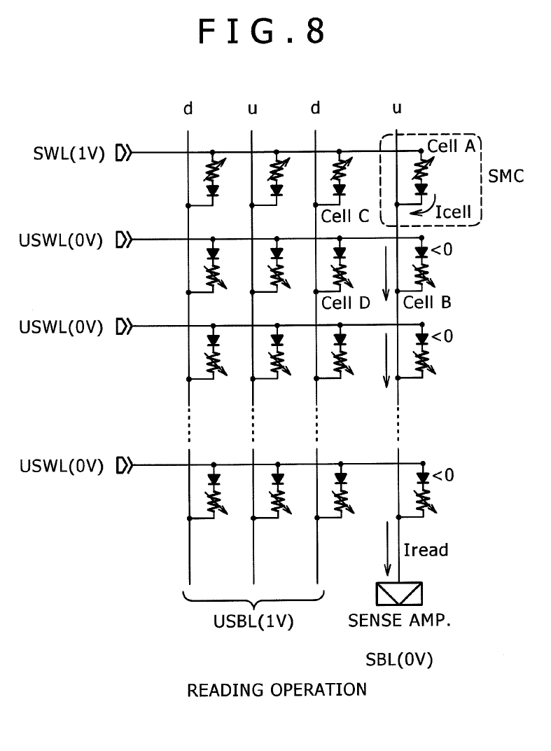

The reading operation of the semiconductor device according to the first embodiment will be described with reference to an equivalent circuit diagram of FIG. 8. In order to select one cell among the memory array and read it, for example, each of the voltages of 1 V, 0 V, 0 V, and 1 V is applied to a word line (SWL: selection word line) to which a selection cell is connected, a word line (USWL: non-selection word line) to which the selection cell is not connected, a bit line (SBL: selection bit line) to which a selection cell is connected, and a bit line (USBL: non-selection bit line) to which a selection cell is not connected. Since the diode hardly generates a leak current of a reverse voltage, current flows in only the selection cell SMC, such that it is possible to determine the resistance state by measuring the current using a sense amplifier.

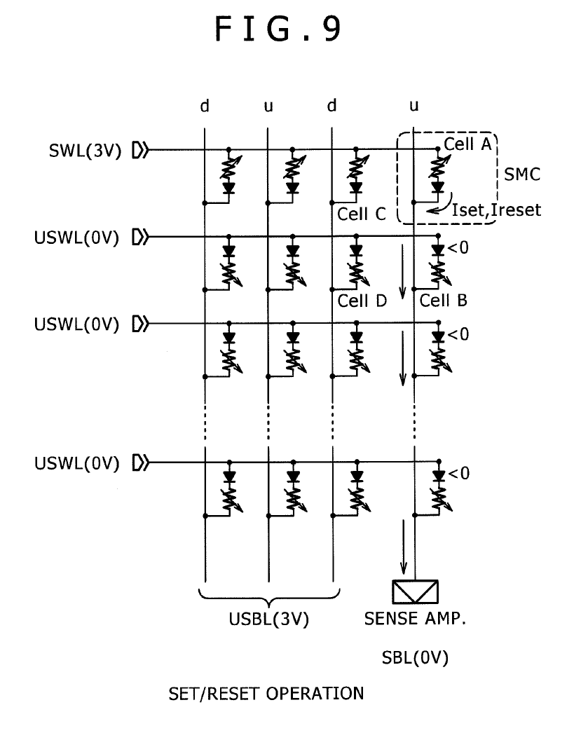

The set/reset operations of the semiconductor device according to the first embodiment will be described with reference to an equivalent circuit diagram of FIG. 9. In order to select one cell among the memory array and perform the set operation, for example, each of the voltages of 2.5 V, 0 V, 0 V, and 2.5 V is applied to the word line (SWL: selection word line) to which the selection cell is connected, the word line (USWL: non-selection word line) to which the selection cell is not connected, the bit line (SBL: selection bit line) to which the selection cell is connected, and the bit line (USBL: non-selection bit line) to which the selection cell is not connected. At this time, since a voltage applied to the diode is a reverse voltage, a current does not flow in CellD that is connected to the non-selection word line and the non-selection bit line. Moreover, since the bit line and the word line are equipotential, a current does not flow in CellB connected to the selection word line and the non-selection bit line and CellD connected to the non-selection word line and the selection bit line. The current flows in only the selection cell SMC and the phase change material is heated by Joule heat. It is preferable that a voltage applied to the selection bit line and the selection word line has enough voltage to heat the phase change material of the selection memory cell to the crystallization temperature. If the voltage is applied for a time sufficient for crystallization (10⁻⁶ seconds or more), the phase change device of the selection cell enters the crystallization state having low resistance, while the state of other cells is not changed.

In order to select one cell among the memory array and perform the reset operation, for example, each of the voltages of 3 V, 0 V, 3 V, and 0 V is applied to the word line (SWL: selection word line) to which the selection cell is connected, the word line (USWL: non-selection word line) to which the selection cell is not connected, the bit line (SBL: selection bit line) to which the selection cell is connected, and the bit line (USBL: non-selection bit line) to which the selection cell is not connected. At this time, since the voltage applied to the diode is the reverse voltage, a current does not flow in CellD, which is connected to the non-selection word line and the non-selection bit line. Moreover, since the bit line and the word line are equipotential, a current does not flow in CellB connected to the selection word line and the non-selection bit line and cellD connected to the non-selection word line and the selection bit line. The current flows in only the selection cell SMC and the phase change material is heated by Joule heat. It is preferable that the voltage applied to the selection bit line and the selection word line has enough voltage to heat the phase change material of the selection memory cell to the temperature of the melting point or more. If the applied voltage is rapidly decreased to 0 and the phase change material is rapidly cooled, the phase change device of the selection cell enters the amorphous state having the high resistance while the other cells do not change the state.

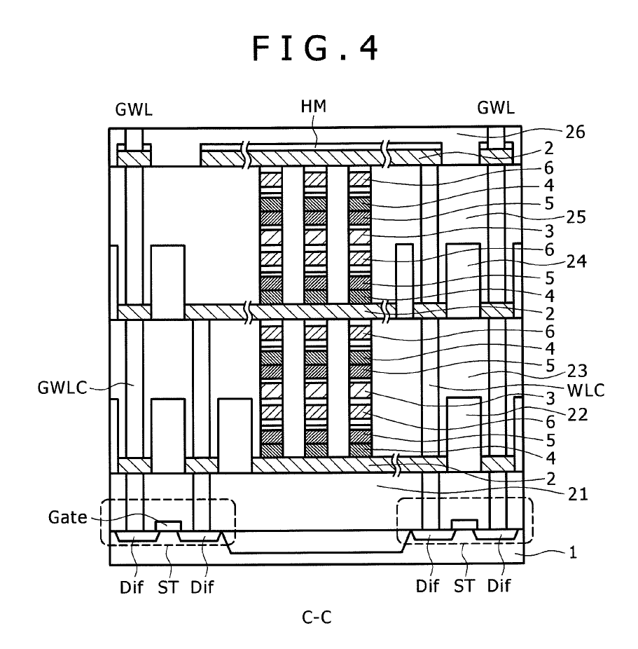

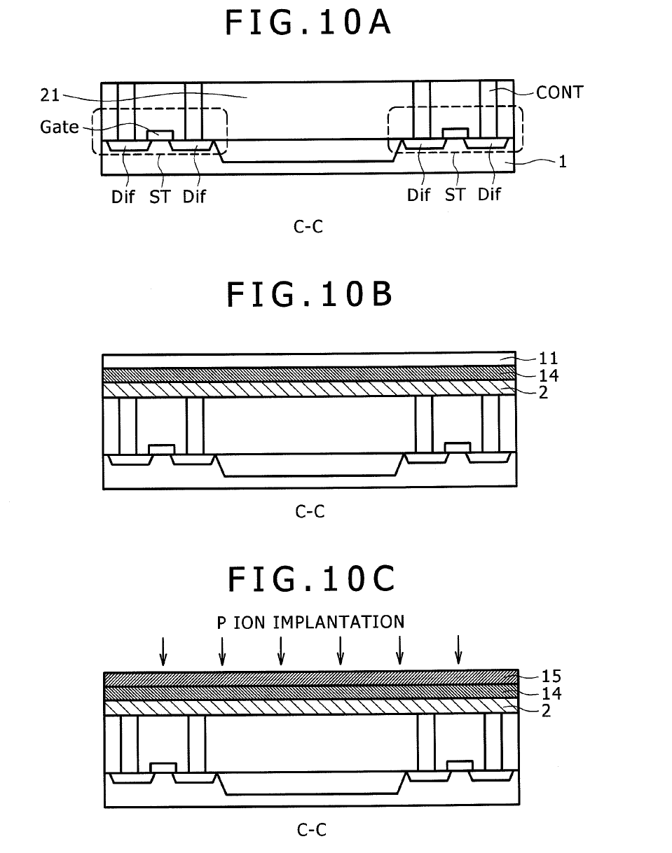

Next, a method of manufacturing the stacked phase change memory will be described with reference to FIGS. 10 to 34. First of all, a selection transistor ST shown in a cross sectional view taken along the line A-A of FIG. 2 and a cross-sectional view taken along the line C-C of FIG. 4 by using a known technology is formed on the silicon substrate. The device on the silicon substrate formed with peripheral circuits necessary for driving the memory array will be formed similar to the above-mentioned device. FIG. 10A shows a state where the selection transistor ST is formed and then, the selection transistor ST is used as an insulating film 21, while the device of the peripheral circuit are buried, thus the surface is smoothed by a chemical mechanical polishing method (CMP method), etc., if necessary, and CONT connecting a diffusion layer Dif of the selection transistor ST and the word line 2 of the memory array to be formed later is formed. Next, a tungsten 2, as an example, that becomes the word line, a B doped amorphous silicon 14, and an amorphous silicon 11 on which the impurities are not doped are deposited (FIG. 10B). A sputtering method is used to deposit the tungsten 2 and a CVD method is used to deposit the B doped amorphous silicon 14 and the amorphous silicon 11 on which the impurities are not doped. The deposition temperature of tungsten is 200° C. or less, the deposition temperature of the B doped amorphous silicon is about 400° C., and the deposition temperature of the amorphous silicon 11 on which the impurities are not doped is about 530° C. Subsequently, phosphorus ions are doped to the amorphous silicon 11 by an ion implantation method (FIG. 10C).

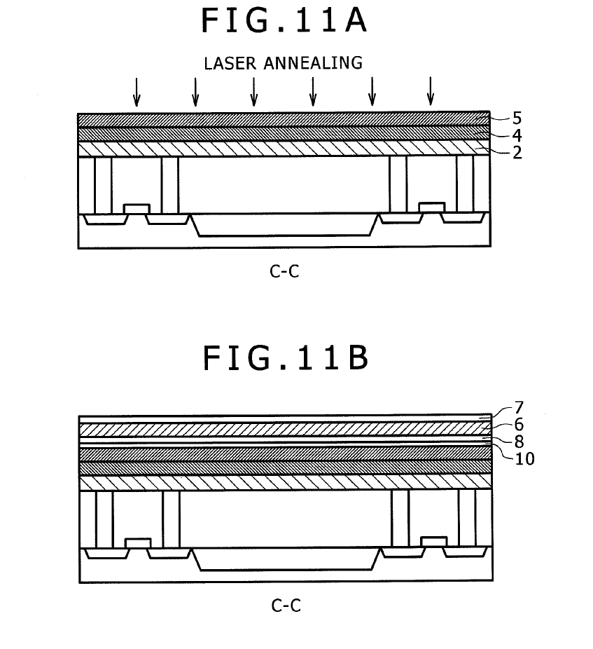

Next, amorphous silicon 14 and 15 are crystallized and the impurities are also activated by a CO₂ laser annealing, for example (FIG. 11A). At this time, since the phase change memory material is not included, it is not necessarily to perform laser annealing, which is performed to reduce the thermal load, instead it is possible to perform the crystallization of the polysilicon and the activation of the impurities by a general heating furnace. However, when the memory array following a second layer is manufactured as described below, laser annealing should be performed without exception. In the first embodiment, the same laser annealing as one used following the second layer is used in the process of FIG. 11A, so that the selection devices following the first layer and the second layer have the same characteristics.

Next, a silicide 10, such as WSi and TiSi₂, is formed on the surface of a P-doped polysilicon 5 and reference numeral 8 (TiN, W, and the like) that becomes a lower electrode of the phase change device, a phase change material 6 (Ge₂Sb₂Te₅, and the like), reference numeral 7 (TiN, W, and the like) that becomes an upper electrode of the phase change device are sequentially deposited (FIG. 11B). The stacked diode structure by the polysilicon can be formed by methods other than the methods shown in FIGS. 10 and 11.

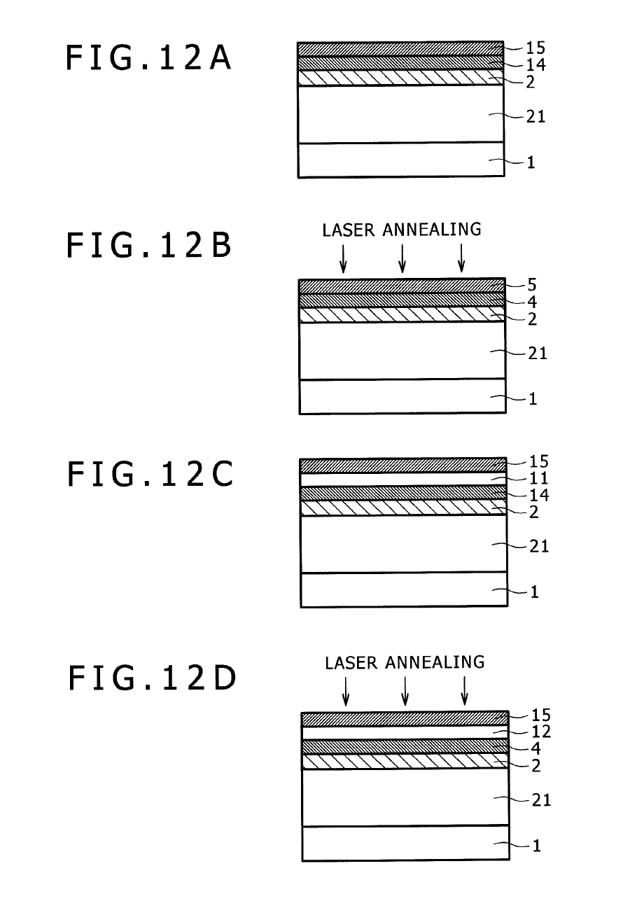

A first method among other methods is the following method shown in FIGS. 12A and 12B. The tungsten 2, as an example, that becomes the word line, the B doped amorphous silicon 14, and the P-doped amorphous silicon 15 are deposited (FIG. 12A). The sputtering method is used to deposit the tungsten 2 and the CVD method is used to deposit the B-doped amorphous silicon 14 and the P-doped amorphous silicon 15. The deposition temperature of tungsten is 200° C. or less, the deposition temperature of the B-doped amorphous silicon is about 400° C., and the deposition temperature of the P-doped amorphous silicon 15 is about 530° C. Subsequently, the crystallization of the amorphous silicon 14 and 15 and the activation of the impurities are performed by CO₂ laser annealing, for example (FIG. 12B). A second method among other methods is the following method shown in FIGS. 12C and 12D. The tungsten 2, as an example, that becomes the word line, the B doped amorphous silicon 14, the amorphous silicon 11 on which the impurities are not doped, and the P-doped amorphous silicon 15 are deposited (FIG. 12C). The sputtering method is used to deposit the tungsten 2 and the CVD method is used to deposit the B doped amorphous silicon 14, the amorphous silicon 11 on which the impurities are not doped, and the P-doped amorphous silicon 15. The deposition temperature of tungsten is 200° C. or less, the deposition temperature of the B doped amorphous silicon is about 400° C., and the deposition temperature of the amorphous silicon 11 on which impurities are not doped and the P-doped amorphous silicon 15 is about 530° C. Subsequently, phosphorus ions are doped to the amorphous silicon 11 by an ion implantation method. Subsequently, the crystallization of the amorphous silicon 14, 11, and 15 and the activation of the impurities are performed by the CO₂ laser annealing, for example (FIG. 12D).

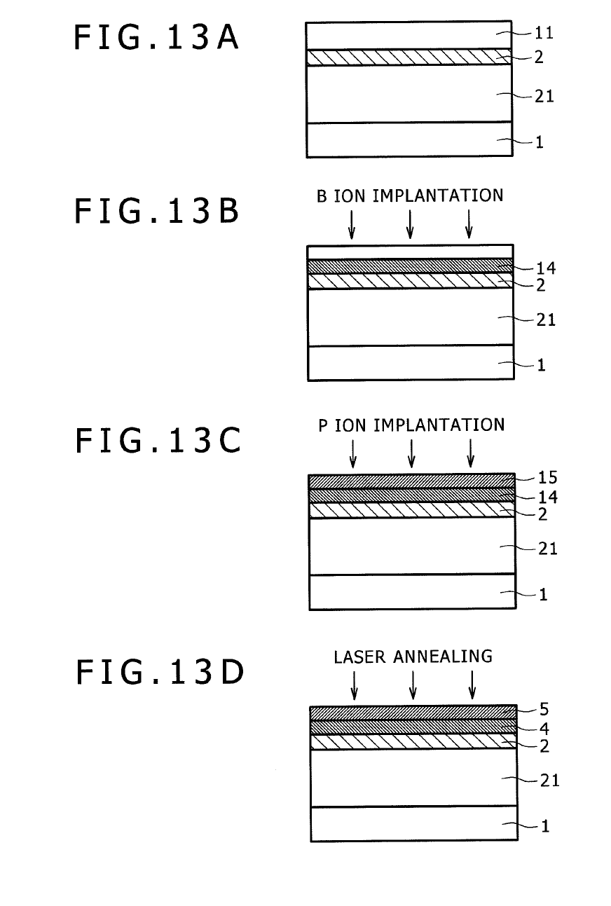

A third method among other methods is the following method shown in FIGS. 13A to 13D. The tungsten 2, as an example, that becomes the word line and the amorphous silicon 11 on which the impurities are not doped are deposited (FIG. 13A). The sputtering method is used to deposit the tungsten 2 and the CVD method is used to deposit the amorphous silicon 11 on which the impurities are not doped. The deposition temperature of tungsten is 200° C. or less and the deposition temperature of the amorphous silicon 11 on which the impurities are not doped is about 530° C. Subsequently, B ions are doped so that the maximum concentration thereof is implanted into a lower half of the amorphous silicon 11 by the ion implantation method (FIG. 13B). Next, P ions are doped so that the maximum concentration thereof is implanted into an upper half of the amorphous silicon 11 by the ion implantation method (FIG. 13C). Thereafter, the crystallization of the amorphous silicon 14 and 15 and the activation of the impurities are performed by the CO₂ laser annealing, for example (FIG. 13D).

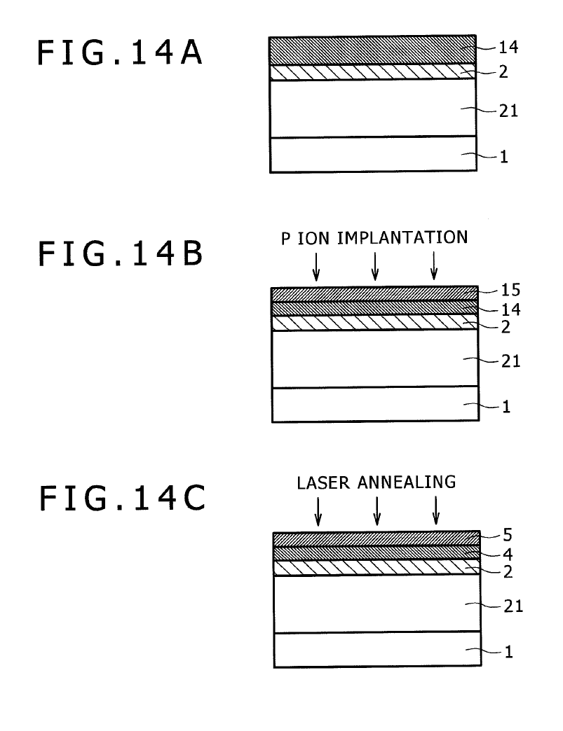

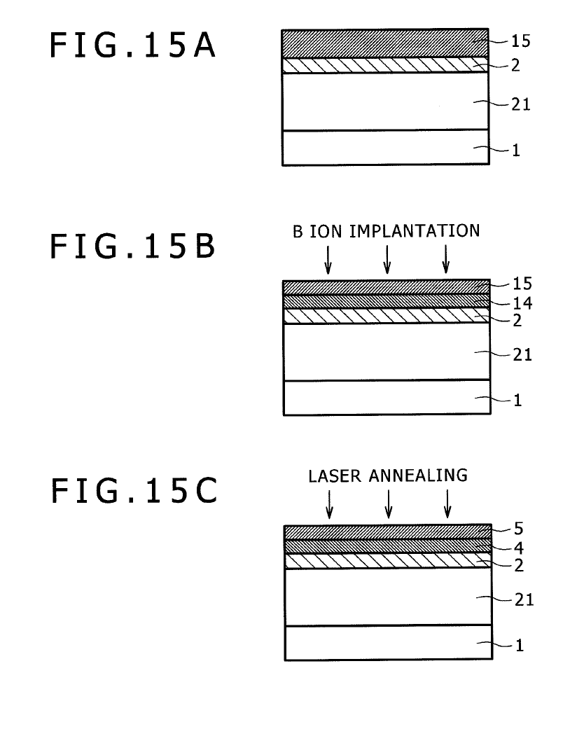

A fourth method among other methods is the following method shown in FIGS. 14A to 14C. The tungsten 2, as an example, that becomes the word line and the B-doped amorphous silicon 14 is deposited (FIG. 14A). The sputtering method is used to deposit the tungsten 2 and the CVD method is used to deposit the B-doped amorphous silicon 14. The deposition temperature of tungsten is 200° C. or less and the deposition temperature of the B-doped amorphous silicon 14 is about 400° C. Subsequently, the P ions are doped so that the maximum concentration thereof is implanted into the upper half of the amorphous silicon 11 by the ion implantation method (FIG. 14B). Next, the crystallization of the amorphous silicon 14 and 15 and the activation of the impurities are performed by CO₂ laser annealing, for example (FIG. 14C). A fifth method among other methods is the following method shown in FIGS. 15A to 15C. The tungsten 2, as an example, that becomes the word line and the P-doped amorphous silicon 15 are deposited (FIG. 15A). The sputtering method is used to deposit the tungsten 2 and the CVD method is used to deposit the P-doped amorphous silicon 15. The deposition temperature of tungsten is 200° C. or less and the deposition temperature of the P-doped amorphous silicon 15 is about 530° C. Subsequently, the B ions are doped so that the maximum concentration thereof is implanted into the lower half of the amorphous silicon 11 by the ion implantation method (FIG. 15B). Next, the crystallization of the amorphous silicon 14 and 15 and the activation of the impurities are performed by the CO₂ laser annealing, for example (FIG. 15C).

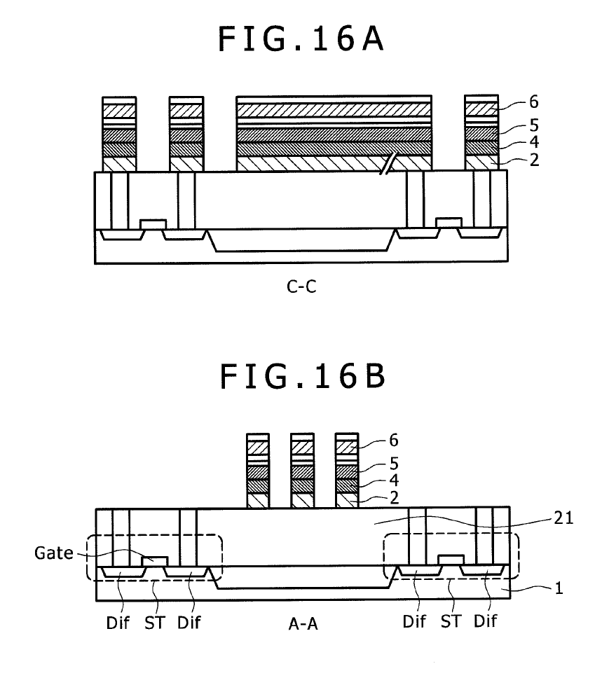

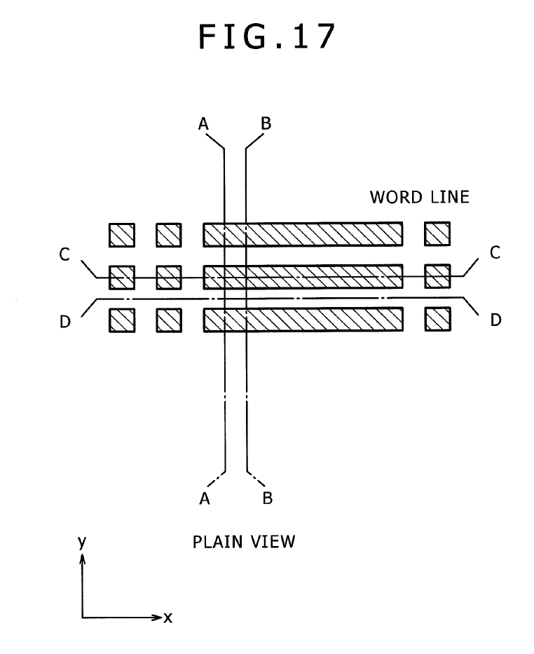

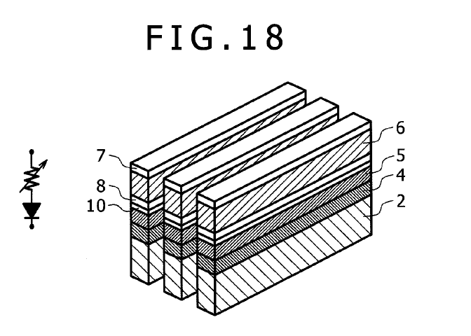

Subsequent to FIG. 11B, the upper electrode 7, the phase change material 6, the lower electrode material 8, the silicide 10, the P-doped polysilicon 5, a B-doped polysilicon 4, and the word line material 2 are patterned in a stripe shape that extends in an x direction. At this time, a pattern is left in a portion in which the contact hole reaching WL and GWL is formed (FIG. 16A). FIG. 16B shows a cross section taken along the line A-A in this process. FIG. 17 is a plan view showing the pattern. Further, FIG. 18 is a cubic diagram showing a portion of the memory array.

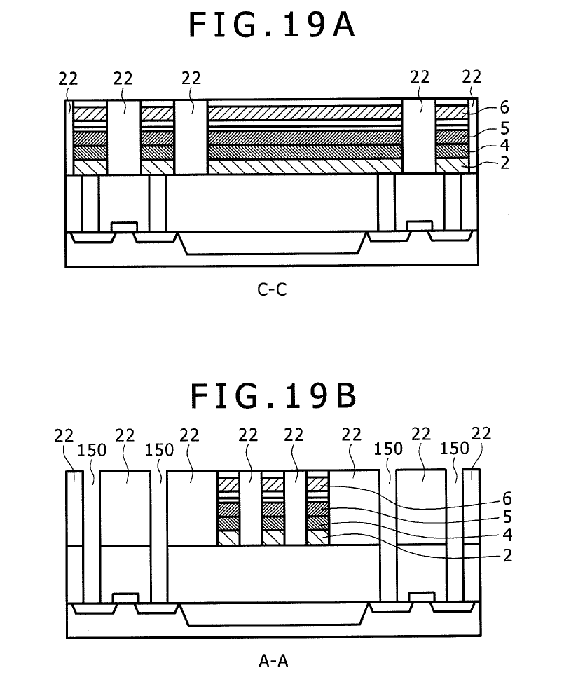

Next, a silicon oxide film 22 is deposited by, for example, the CVD method and in FIG. 16, a patterned space is completely buried. Subsequently, the upper electrode 7 whose surface is smoothed by, for example, the CMP method is exposed, such that a contact hole 150 for connecting the bit line and the diffusion layer of the selection transistor is formed (FIGS. 19A and 19B).

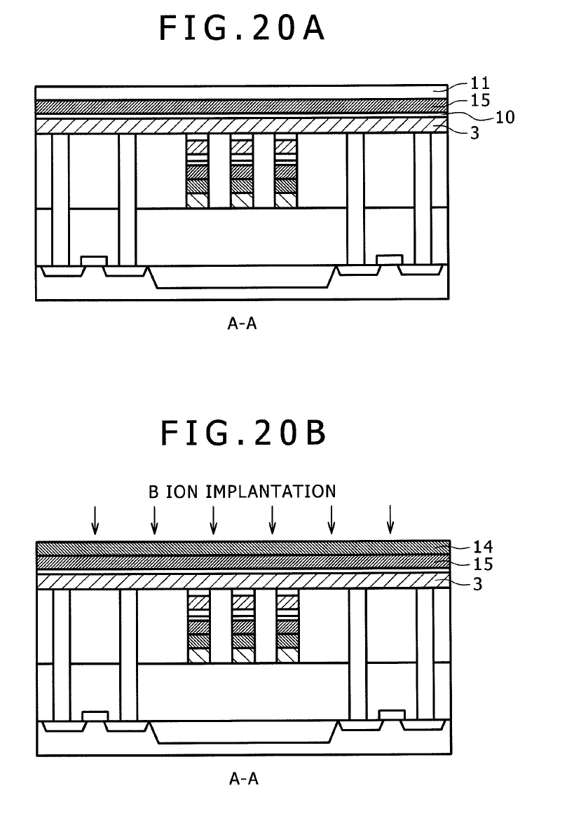

Then, W is buried in, for example, the contact hole 150 by, for example, the CVD method or Ti, TiN, or W are sequentially buried in, for example, the contact hole 150 by the CVD method, for example. W deposited on the upper surface is removed by, for example, the CMP method, thereby forming a plug. Next, the material (for example, tungsten) that becomes the bit line 3 is deposited and a barrier metal, such as TiN, or a silicide, such as WSi, TiSi₂, or the film 10 on which the barrier metal and the silicide are sequentially deposited are formed and the P-doped amorphous silicon 15 is deposited. Next, the amorphous silicon 11 on which the impurities are not doped is deposited (FIG. 20A). Next, the B ions are doped to the amorphous silicon 11 by the ion implantation method (FIG. 20B).

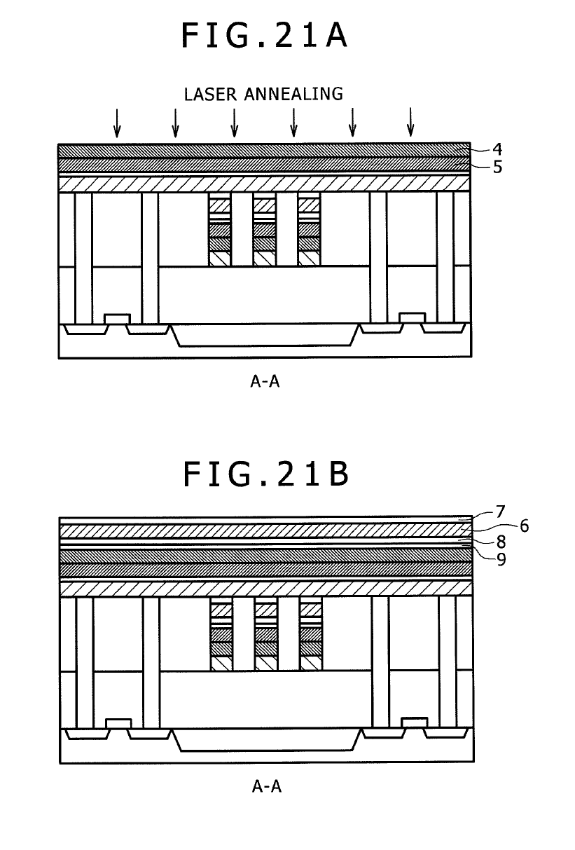

Next, the crystallization of the amorphous silicon 14 and 15 and the activation of the impurities are performed by CO₂ laser annealing, for example (FIG. 21A). Laser annealing sufficiently performs the crystallization of the amorphous silicon and the activation of the impurities and is performed in order to make the current drivability of the diode, which becomes the selection device, sufficient and to reduce the thermal load to the phase change memory material 6 configuring the memory array in the first layer while not reducing yield.

Generally, in order to crystallize the polysilicon using a furnace body, there is a need to perform the heat treatment at a temperature of 700° C. or more for a long time. Meanwhile, the yield of the phase change device is reduced to approximately 0% due to the thermal load. If annealing is performed in a short time by laser annealing in a state where there is bit line material 3 between the phase change material 6 and the amorphous silicon of the second layer subjected to the crystallization, it is possible to suppress the temperature increase of the phase change material 6 and to reduce the thermal load when the amorphous silicon of the second layer is crystallized, as compared to a case of furnace body heating.

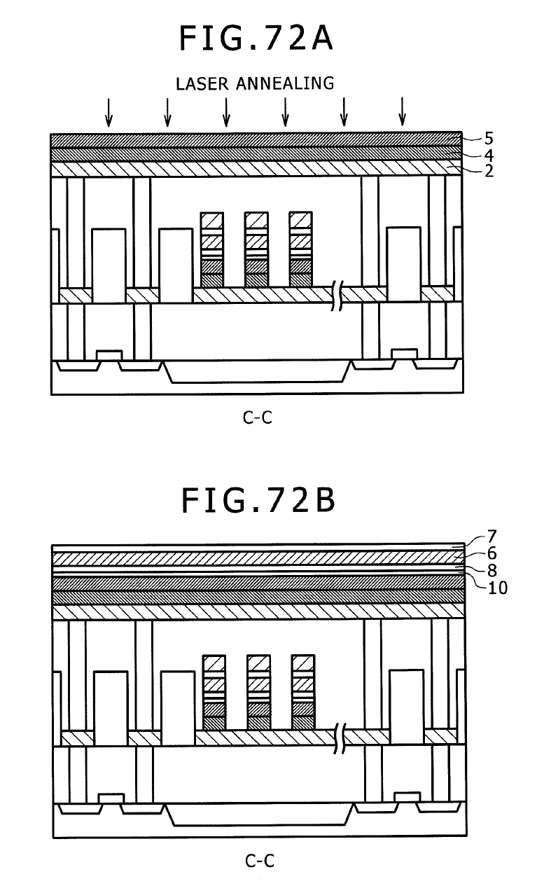

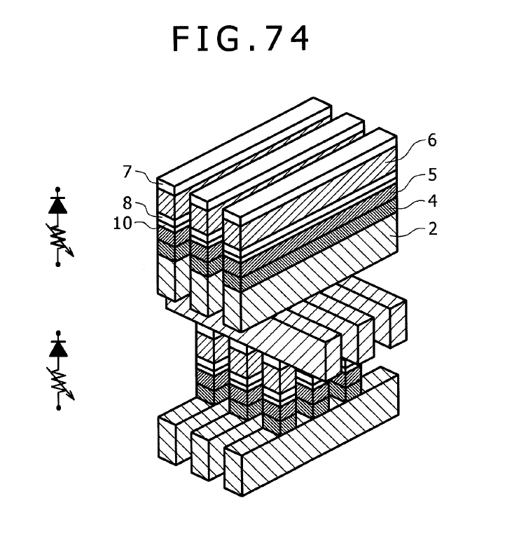

Next, the silicide 9, such as WSi, TiSi₂, is formed on the surface of the B-doped polysilicon 4 and reference numeral 8 that becomes the lower electrode (TiN, W, and the like) of the phase change device, the phase change material 6 (Ge₂Sb₂Te₅, and the like), and reference numeral 7 (TiN, W, and the like) that becomes the upper electrode of the phase change device are sequentially deposited (FIG. 21B). The stacked PN diode structure by the polysilicon can also be formed by methods other than the methods shown in FIGS. 72 to 74.

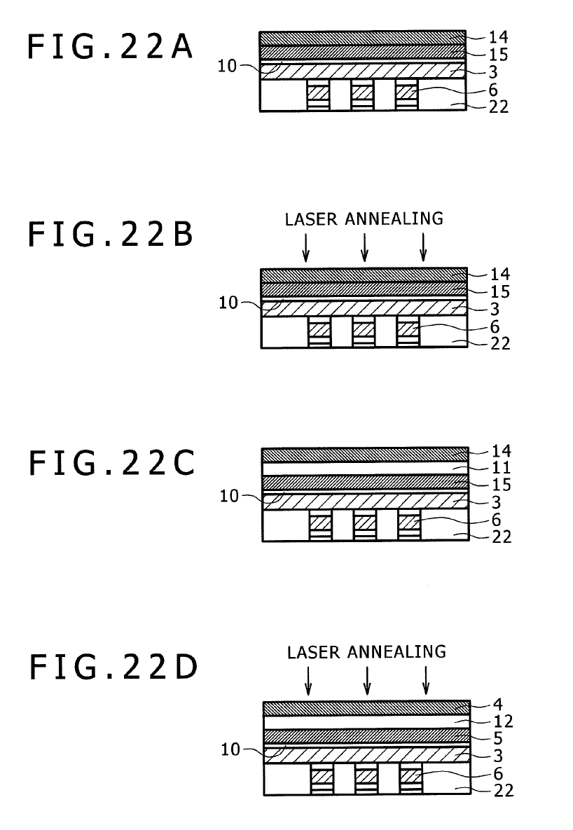

A first method among other methods is the following method shown in FIGS. 22A and 22B. The tungsten 3, as an example, that becomes the line, the barrier metal, such as TiN, or the silicide, such as WSi, TiSi₂, or the film 10 on which the barrier metal and the silicide are sequentially deposited are formed and the P-doped amorphous silicon 15 and the B-doped amorphous silicon 14 are deposited (FIG. 22A). The sputtering method is used to deposit the tungsten 3 and the CVD method is used to deposit the B-doped amorphous silicon 14 and the P-doped amorphous silicon 15. The deposition temperature of tungsten is 200° C. or less, the deposition temperature of the B-doped amorphous silicon is about 400° C., and the deposition temperature of the P-doped amorphous silicon 15 is about 530° C. Subsequently, the crystallization of the amorphous silicon 14 and 15 and the activation of the impurities are also performed by CO₂ laser annealing, for example (FIG. 22B).

A second method among other methods is the following method shown in FIGS. 22C and 22D. The tungsten 3, as an example, that becomes the line, the barrier metal, such as TiN, or the silicide, such as WSi, TiSi₂, or the film 10 on which the barrier metal and the silicide are sequentially deposited are formed and the P-doped amorphous silicon 15, the amorphous silicon 11 on which the impurities are not doped, and the B-doped amorphous silicon 14 are deposited (FIG. 22C). The sputtering method is used to deposit the tungsten 3 and the CVD method is used to deposit the B-doped amorphous silicon 14, the amorphous silicon 11 on which the impurities are not doped, and the P-doped amorphous silicon 15. The deposition temperature of tungsten is 200° C. or less, the deposition temperature of the B-doped amorphous silicon is about 400° C., and the deposition temperature of the amorphous silicon 11 on which the impurities are not doped and the P-doped amorphous silicon 15 is about 530° C. Subsequently, the crystallization of the amorphous silicon 14, 11, and 15 and the activation of the impurities are also performed by the CO₂ laser annealing, for example (FIG. 22D).

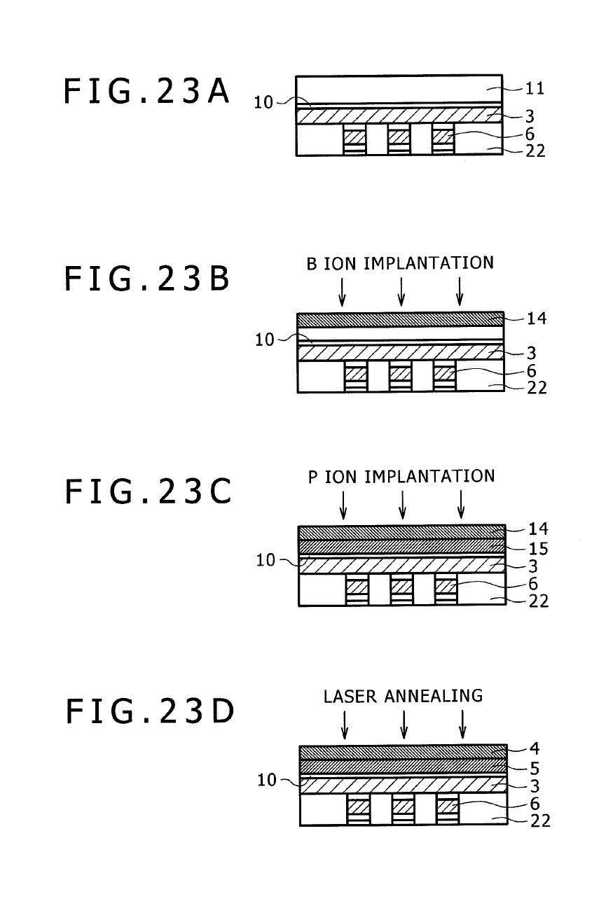

A third method among other methods is the following method shown in FIGS. 23A to 23D. The tungsten 3, as an example, that becomes the line, the barrier metal, such as TiN, or the silicide, such as WSi, TiSi₂, or the film 10 on which the barrier metal and the silicide are sequentially deposited are formed and the amorphous silicon 11 on which the impurities are not doped is deposited (FIG. 23A). The sputtering method is used to deposit the tungsten 3 and the CVD method is used to deposit the amorphous silicon 11 on which the impurities are not doped. The deposition temperature of tungsten is 200° C. or less and the deposition temperature of the amorphous silicon 11 on which the impurities are not doped is about 530° C. Subsequently, the B ions are doped so that the maximum concentration thereof is implanted into the upper half of the amorphous silicon 11 by the ion implantation method (FIG. 23B). Next, the P ions are doped so that the maximum concentration thereof is implanted into the lower half of the amorphous silicon 11 by the ion implantation method (FIG. 23C). Thereafter, the crystallization of the amorphous silicon 14 and 15 and the activation of the impurities are also performed by the CO₂ laser annealing, for example (FIG. 23D).

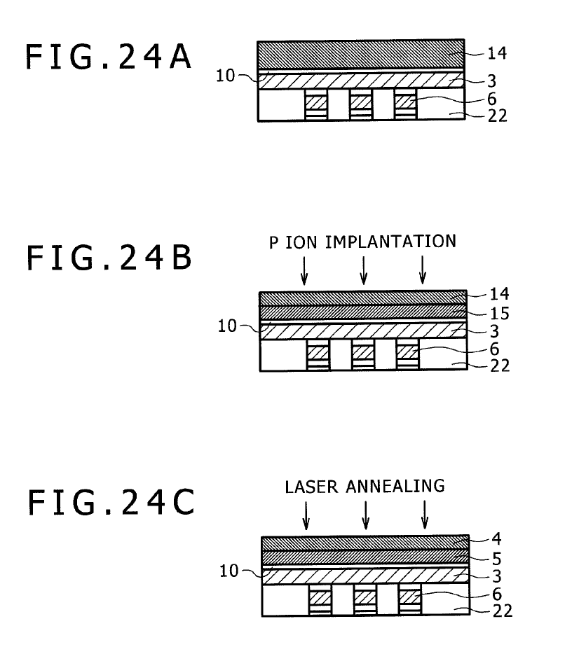

A fourth method among other methods is the following method shown in FIGS. 24A to 24C. The tungsten 3, as an example, that becomes the line, the barrier metal, such as TiN, or the silicide, such as WSi, TiSi₂, or the film 10 on which the barrier metal and the silicide are sequentially deposited are formed and the B-doped amorphous silicon 14 is deposited (FIG. 24A). The sputtering method is used to deposit the tungsten 3 and the CVD method is used to deposit the B-doped amorphous silicon 14. The deposition temperature of tungsten is 200° C. or less and the deposition temperature of the B-doped amorphous silicon 14 is about 400° C. Next, the P ions are doped so that the maximum concentration thereof is implanted into the lower half of the amorphous silicon 11 by the ion implantation method (FIG. 24B). Thereafter, the crystallization of the amorphous silicon 14 and 15 and the activation of the impurities are also performed by CO₂ laser annealing, for example (FIG. 24C).

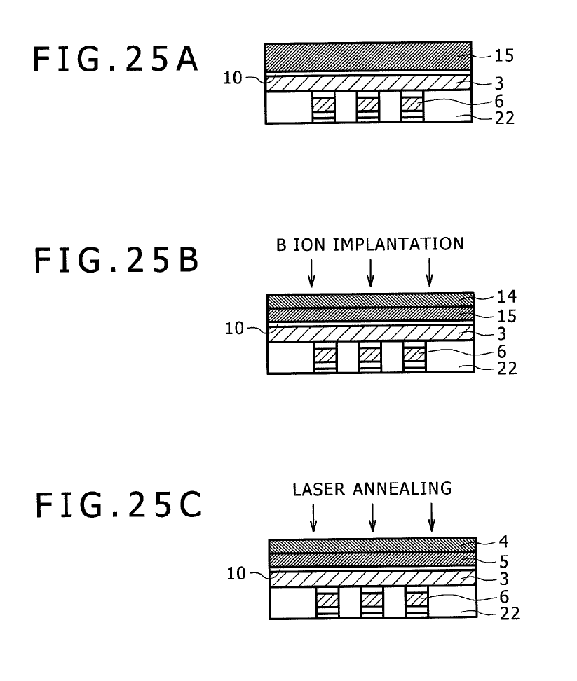

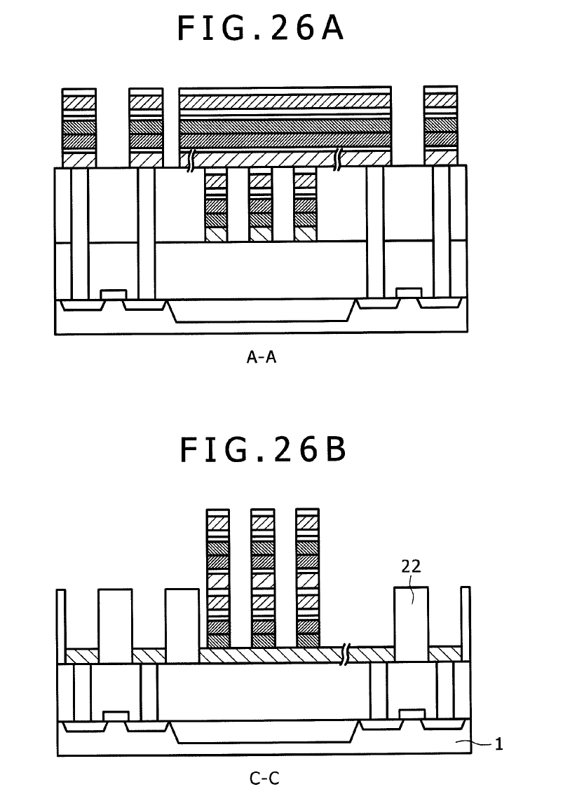

A fifth method among other methods is the following method shown in FIGS. 25A to 25C. The tungsten 3, as an example, that becomes the bit line and the P-doped amorphous silicon 15 are deposited (FIG. 25A). The sputtering method is used to deposit the tungsten 3 and the CVD method is used to deposit the P-doped amorphous silicon 15. The deposition temperature of tungsten is 200° C. or less and the deposition temperature of the P-doped amorphous silicon 15 is about 530° C. Next, the B ions are doped so that the maximum concentration thereof is implanted into the upper half of the amorphous silicon 11 by the ion implantation method (FIG. 25B). Thereafter, the crystallization of the amorphous silicon 14 and 15 and the activation of the impurities are also performed by the CO₂ laser annealing, for example (FIG. 25C).

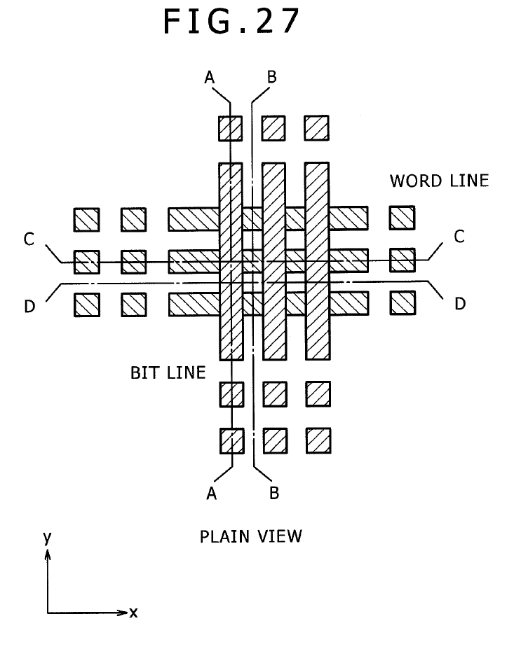

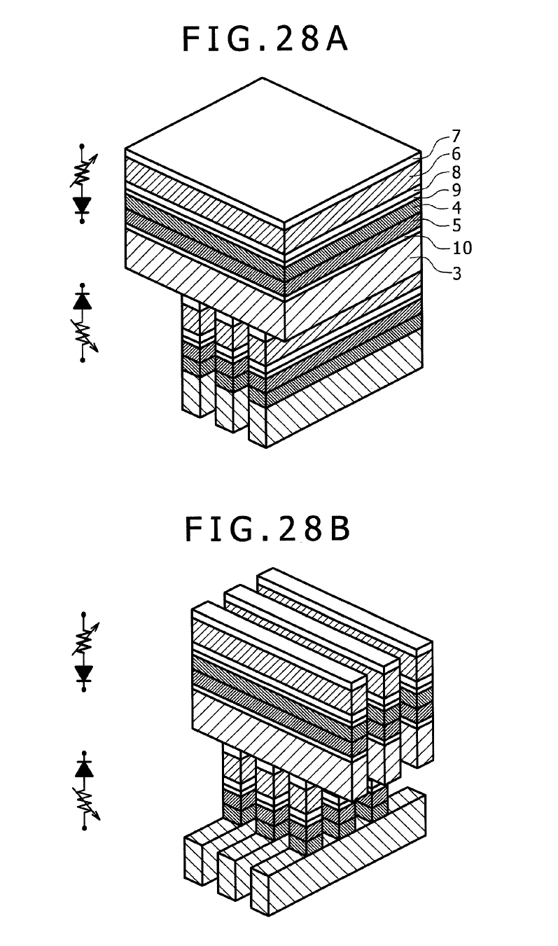

Subsequent to FIG. 21B, the upper electrode 7, the phase change material 6, the lower electrode material 8, the silicide 9, the B-doped polysilicon 4, the P-doped polysilicon 5, the barrier metal such as TiN, or the silicide, such as WSi, TiSi₂, and the film 10 on which the barrier metal and the silicide are sequentially deposited are formed and the bit line material 3, the upper electrode 7 of the memory array in the first layer, the phase change material 6 of the memory array in the first layer, the lower electrode 8 of the memory array in the first layer, the film 10 of the memory array in the first layer, the P-doped polysilicon 5 of the memory array in the first layer, and the B-doped polysilicon 4 of the memory array in the first layer are patterned in a stripe shape that extends in a y direction. At this time, a pattern is left in a portion in which the contact hole reaching BL and GBL is formed (FIG. 26A). FIG. 26B shows a cross section taken along the line C-C in this process. FIG. 27 is a plan view showing the pattern. Further, FIG. 28B is a cubic diagram showing a portion of the memory array after patterning FIG. 28A. The memory array of the second layer is patterned in a stripe shape, such that the cross point structure of the memory array in the first layer is completed.

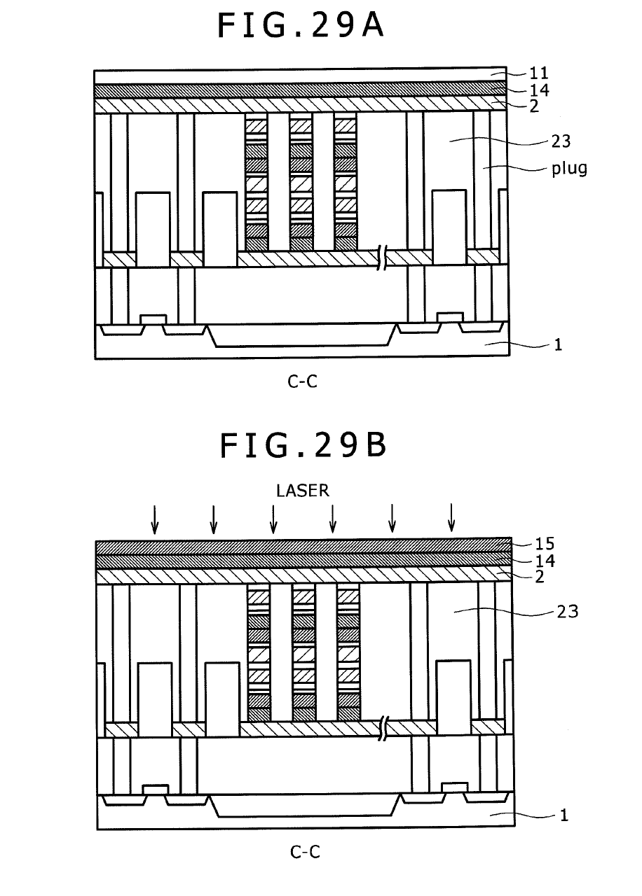

Next, a silicon oxide film 23 is deposited by, for example, the CVD method and in FIG. 26, a patterned space is completely buried. Subsequently, the upper electrode 7 whose surface is smoothed by, for example, the CMP method is exposed, such that the contact hole 150 reaching the word line and the pattern of the first layer is formed. Thereafter, W is buried in, for example, the contact hole by the CVD method, for example. W deposited on the upper surface is removed by, for example, the CMP method, thereby forming a plug. Next, tungsten, as an example, that becomes the word line, the B-doped amorphous silicon 14, and the amorphous silicon 11 on which the impurities are not doped are deposited (FIG. 29A). The sputtering method is used to deposit the tungsten 2 and the CVD method is used to deposit the B-doped amorphous silicon 14 and the amorphous silicon 11 on which the impurities are not doped. The deposition temperature of tungsten is 200° C. or less and the deposition temperature of the B-amorphous silicon is about 400° C., and the deposition temperature of the amorphous silicon 11 on which the impurities are not doped is about 530° C. Subsequently, the phosphorus ions are doped to the amorphous silicon 11 by the ion implantation method. Then, the crystallization of the amorphous silicon 14 and 15 and the activation of the impurities are also performed by the CO₂ laser annealing, for example (FIG. 29B).

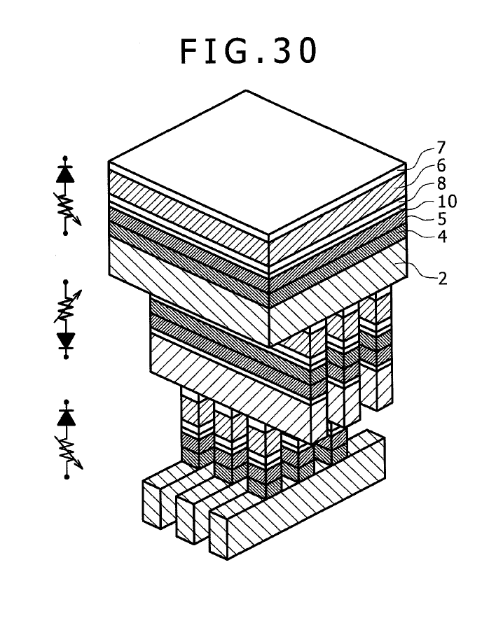

Next, the barrier metal, such as TiN, or the silicide 10, such as WSi, TiSi₂ is formed on the surface of the P-doped polysilicon 5 and reference numeral 8 (TiN, W, and the like) that becomes the lower electrode of the phase change device, the phase change material 6 (Ge₂Sb₂Te₅, and the like), reference numeral 7 (TiN, W, and the like) that becomes the upper electrode of the phase change device are sequentially deposited (FIG. 30).

The stacked PN diode structure by the polysilicon can be formed by methods other than the methods shown in FIG. 29. As described above, the first method (FIGS. 22A and 22B), the second method (FIGS. 22C and 22D), the third method (FIGS. 23A to 23D), the fourth method (FIGS. 24A to 24C), and the fifth method (FIGS. 25A to 25C) among other methods can be used.

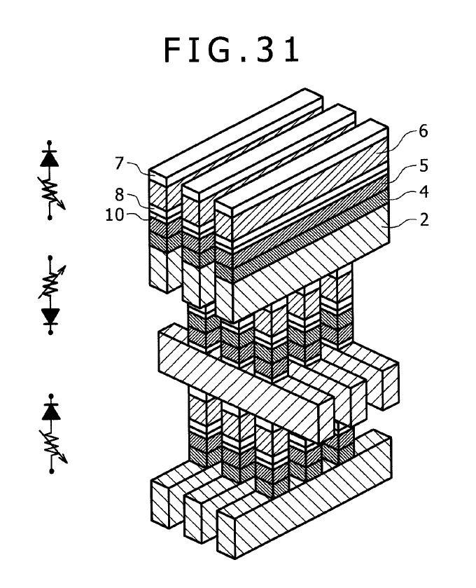

Subsequently, the upper electrode 7, the phase change material 6, the lower electrode material 8, the silicide 10, the P-doped polysilicon 5, the B-doped polysilicon 4, the word line material 2, the upper electrode 7 of the memory array in the second layer, the phase change material 6 of the memory array in the second layer, the lower electrode 8 of the memory array in the second layer, the silicide 9 of the memory array in the second array, the B-doped polysilicon 4 of the memory array in the second layer, and the P-doped polysilicon 5 of the memory array in the second layer are patterned in a stripe shape that extends in an x direction. Moreover, FIG. 31 shows a cubic diagram of a portion of the memory array. The memory array in the third layer is patterned in a stripe shape, such that the cross point structure of the memory array in the second layer is completed.

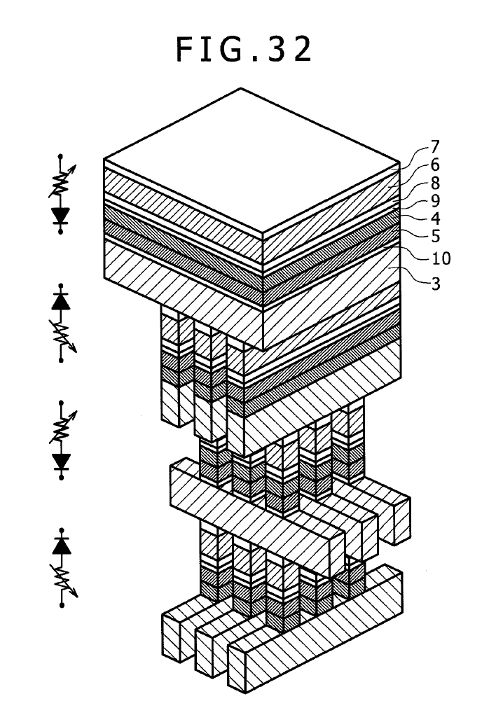

Hereinafter, a four-layer stacked cross point memory can be completed by repeating the above-mentioned processes. Subsequent to FIG. 31, a silicon oxide film 24 is deposited by, for example, the CVD method and in FIG. 31, a patterned space is completely buried. Subsequently, the upper electrode 7 whose surface is smoothed by, for example, the CMP method is exposed. Next, after the contact hole reaching the diffusion layer of the selection transistor connected to the bit line is formed, W is buried in the contact hole by, for example, the CVD method and W deposited on the upper surface is removed by the CMP method, thereby forming the plug. The bit line 3, the barrier metal film, or the silicide 10 is formed by the same process as the memory array in the second layer and the stacked structure of the P-doped polysilicon, the B-doped polysilicon, the silicide 9, and the lower electrode 8, the phase change material 6, the upper electrode 7 is formed (FIG. 32).

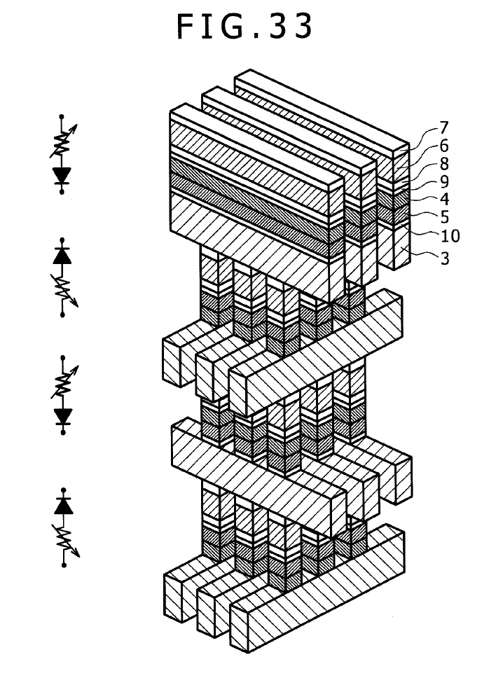

Next, the upper electrode 7, the phase change material 6, the lower electrode 8, the silicide 9, the B-doped polysilicon 4, the p-doped polysilicon 5, the barrier metal film or the silicide 10, the bit line material 3, the upper electrode 7 of the memory array in the third layer, the phase change material 6 of the memory array in the third layer, the lower electrode 8 of the memory array in the third layer, the barrier metal film of the memory array in the third layer or the silicide 10, the P-doped polysilicon 5 of the memory array in the third array, and the B-doped polysilicon 4 of the memory array in the third layer are patterned in a stripe shape that extends in a y direction (FIG. 33). The memory array in the fourth layer is patterned in a stripe shape, such that the cross point structure of the memory array in the third layer is completed.

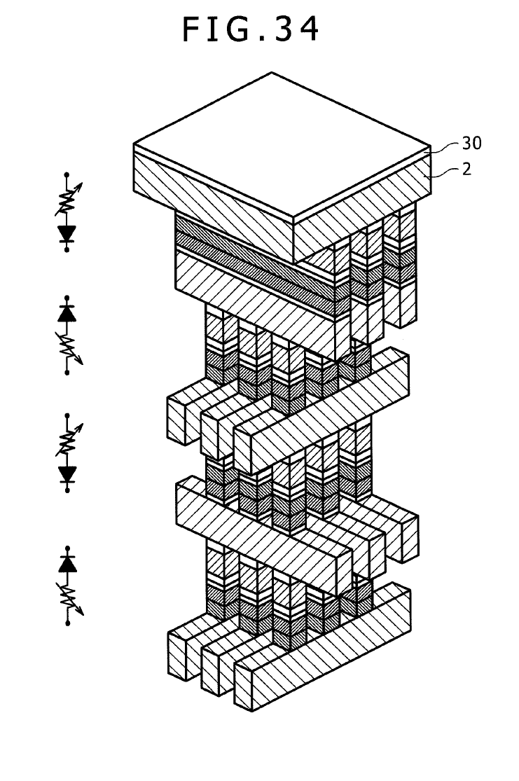

Next, a silicon oxide film 25 is deposited by, for example, the CVD method and in FIG. 33, a patterned space is completely buried. Subsequently, after the upper electrode 7 whose surface is smoothed by, for example, the CMP method is exposed and the contact hole reaching the pattern of the word line in the second layer is formed, W is buried in, for example, the contact hole by the CVD method, for example and W deposited on the upper surface is removed by, for example, the CMP method, thereby forming a plug. Next, tungsten 2, as an example, that becomes the word line and a silicon oxide film 30, as an example, that becomes a hard mask are deposited (FIG. 34).

Next, the hard mask 30, the word line material 2, the upper electrode 7, the phase change material 6, the lower electrode 8, the silicide 9, the B doped polysilicon 4, and the P doped polysilicon 5 are patterned in a stripe shape that extends in an x direction. Next, after a silicon oxide film 26 is deposited by, for example, the CVD method and in FIG. 34, a patterned space is completely buried, the surface is smoothed by the CMP method, for example. Thereafter, the plug to connect the bit line pattern, the word line pattern of the top layer and GWL and GBL is formed. Thereafter, although not shown in the drawings, the semiconductor memory device in which a well of the selection transistor ST, a wiring for supplying electricity to gate, GBL, and GWL are formed is completed.

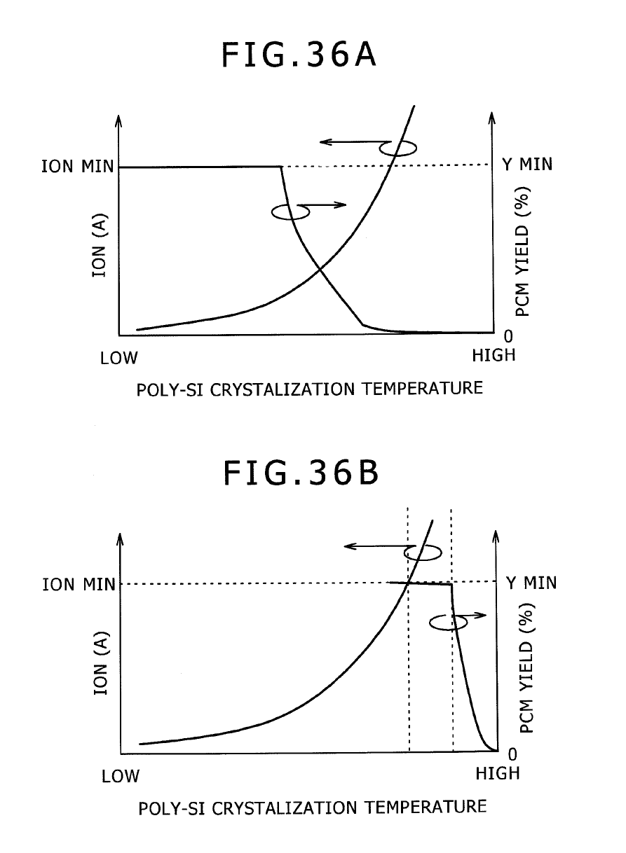

If the semiconductor memory device is manufactured according to the method of the related art performing the polysilicon crystallization of the transistor that becomes the selection device by the furnace body heating for a long time, it is impossible to achieve both the current drivability of the selection device of the stacked phase change memory and yield Ymin or more of the phase change device (FIG. 36A). Ymin is a minimum yield value that can reduce costs by stacking the phase change memory. According to the method of the present invention, it is possible to achieve both as well as to reduce costs of the phase change memory and to make capacity of the phase change memory large by the stacking (FIG. 36B).

In the first embodiment, although the variable resistance element becomes the phase change memory and the transistor that becomes the selection device is formed of the polysilicon, the variable resistance element can be formed of ReRAM, such as NiO, CuO, TiO₂, and the selection transistor can be formed of semiconductor other than silicon, such as Ge, SiGe. Even in using the same method as above, the same effect can be obtained.

### Second Embodiment

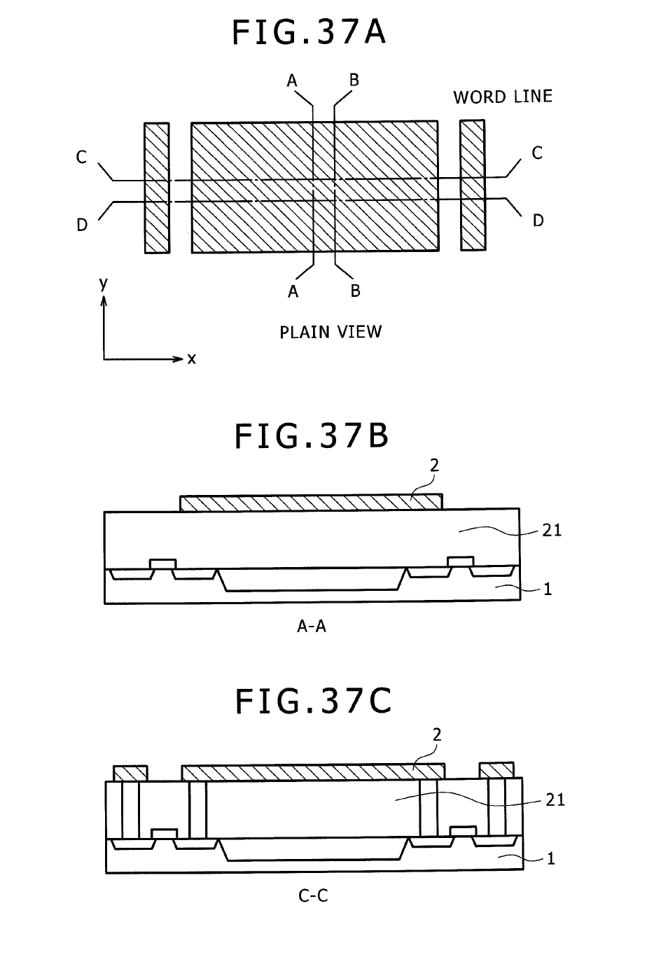

In the first embodiment, when the crystallization of the amorphous silicon and the activation of the impurities are performed by laser annealing, the bit line material and the word line material just below the amorphous silicon covers the entire semiconductor main plane, while as described in a second embodiment, in performing laser annealing the manufacturing method that does not cover the entire semiconductor main plane with the word line material and the bit line material can be also permitted. FIGS. 37 to 46 show a method of manufacturing the semiconductor memory device according to the second embodiment.

First of all, like the first embodiment, the selection transistor and the peripheral circuit device are formed on the semiconductor substrate 1 and the insulating film 21 is formed thereon. Next, the word line material (for example, W) is deposited by the sputtering method. The deposition temperature of tungsten is 200° C. or less. Subsequently, the word line material is patterned so that it is formed as shown in FIGS. 37A to 37C.

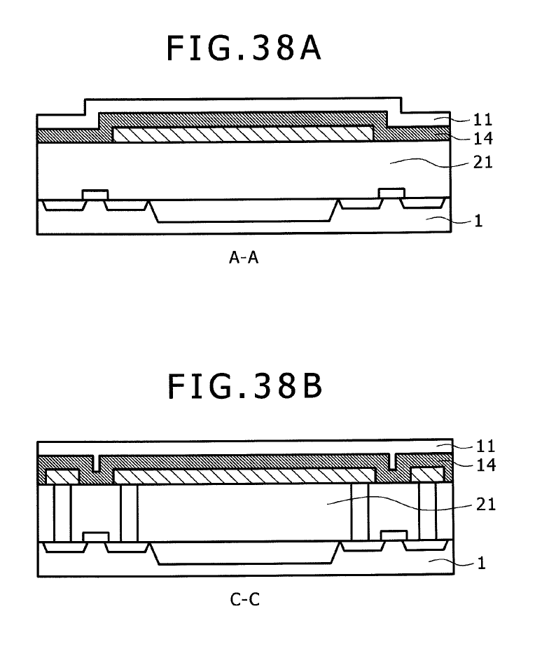

Then, the B-doped amorphous silicon 14 and the amorphous silicon 11 on which the impurities are not doped are deposited (FIG. 38A). The CVD method is used to deposit the B-doped amorphous silicon 14 and the amorphous silicon 11 on which the impurities are not doped. The deposition temperature of the B-doped amorphous silicon is about 400° C. and the deposition temperature of the amorphous silicon 11 on which the impurities are not doped is about 530° C.

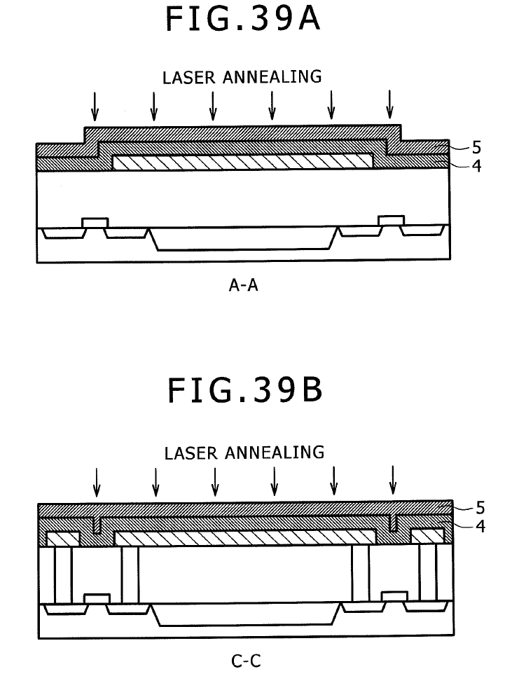

Next, the phosphorous ions are doped to the amorphous silicon 11 by the ion implantation method and then, the crystallization of the amorphous silicon 14 and 15 and the activation of the impurities are performed by, for example, CO₂ laser annealing (FIGS. 39A and 39B). At this time, since the phase change memory material is not included, it is not necessarily to perform laser annealing that is performed to reduce the thermal load, but it is possible to perform the crystallization of the polysilicon and the activation of the impurities by the general heating furnace. However, when the memory array following the second layer is manufactured as described below, laser annealing should be performed without exception. In the second embodiment, since the selection devices following the first layer and the second layer have the same characteristics, laser annealing as well as the crystallization of the polysilicon forming the diode following the second layer is used.

When crystallizing the amorphous silicon by laser annealing, the laser is not irradiated on the entire semiconductor main plane at the same time, but irradiated on a part thereof several times. At this time, if the word line material 2 that becomes the metal film is connected to the entire semiconductor main plane, heat from the laser irradiating part is transferred to the word line material 2 and heat-dissipated, such that a high laser power is needed for the crystallization. The crystallization of the amorphous silicon and the activation of the impurities can be achieved using small laser power by patterning the metal film just below the amorphous silicon subjected to the crystallization according to the second embodiment.

Next, the silicide 10, such as WSi, TiSi₂ is formed on the surface of the P-doped polysilicon 5 and reference numeral 8 (TiN, W, and the like) that becomes the lower electrode of the phase change device, the phase change material 6 (Ge₂Sb₂Te₅, and the like), reference numeral 7 (TiN, W, and the like) that becomes the upper electrode of the phase change device are sequentially deposited. The stacked PN diode structure using the polysilicon can be formed by methods other than the methods shown in FIGS. 38 and 39.

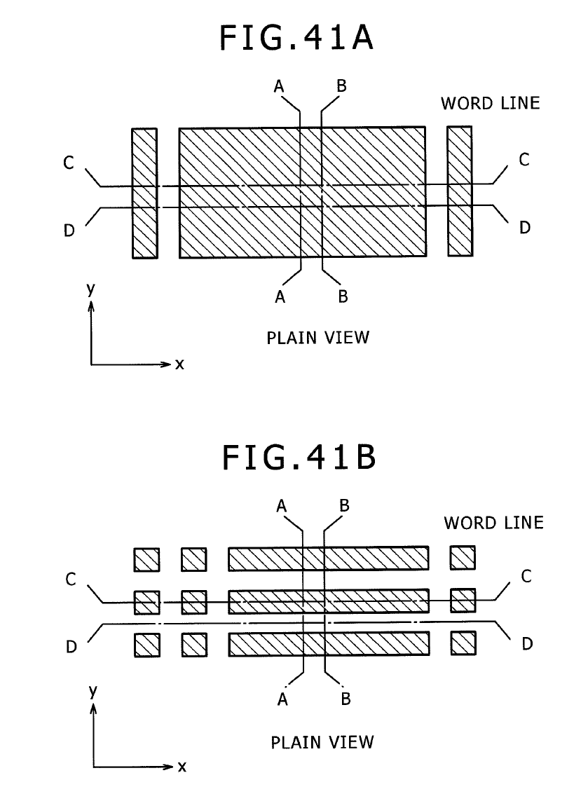

As described in the first embodiment, the first method (FIGS. 12A and 12B), the second method (FIGS. 12C and 12D), the third method (FIGS. 13A to 13D), the fourth method (FIGS. 14A to 14C), and the fifth method (FIGS. 15A to 15C) among other methods can be used on the patterned word line 2. Subsequently, the upper electrode 7, the phase change material 6, the lower electrode 8, the silicide 10, the P-doped polysilicon 5, the B-doped polysilicon 4, and the word line material 2 are patterned in a stripe shape that extends in an x direction. In the plan view, FIG. 41A shows the change to FIG. 41B. At this time, the pattern is left in a portion in which the contact hole reaching WL and GWL is formed.

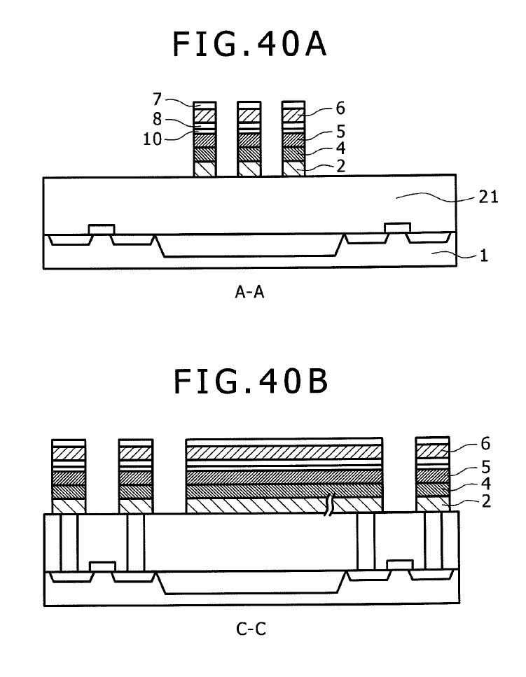

Next, the silicon oxide film 22 is deposited by, for example, the CVD method and in FIGS. 40A and 40B, a patterned space is completely buried. Subsequently, the upper electrode 7 whose surface is smoothed by, for example, the CMP method is exposed, such that the contact hole connecting the bit line and the diffusion layer of the selection transistor is formed. Next, W is buried in, for example, the contact hole by, for example, the CVD method or Ti, TiN, or W is sequentially buried in, for example, the contact hole by the CVD method, for example. W deposited on the upper surface is removed by, for example, the CMP method, thereby forming a plug and then depositing the bit line material 3.

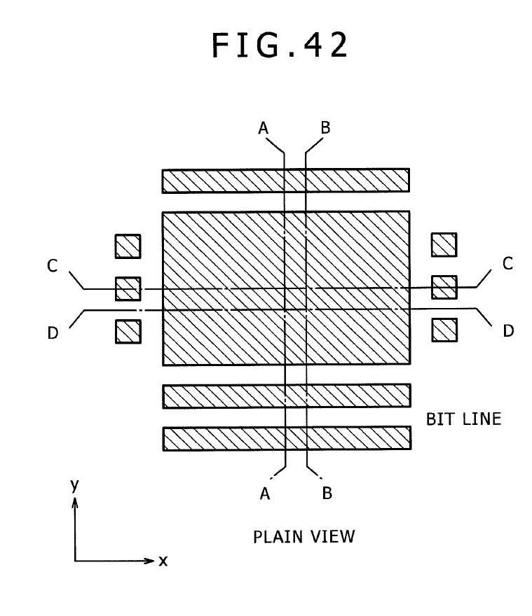

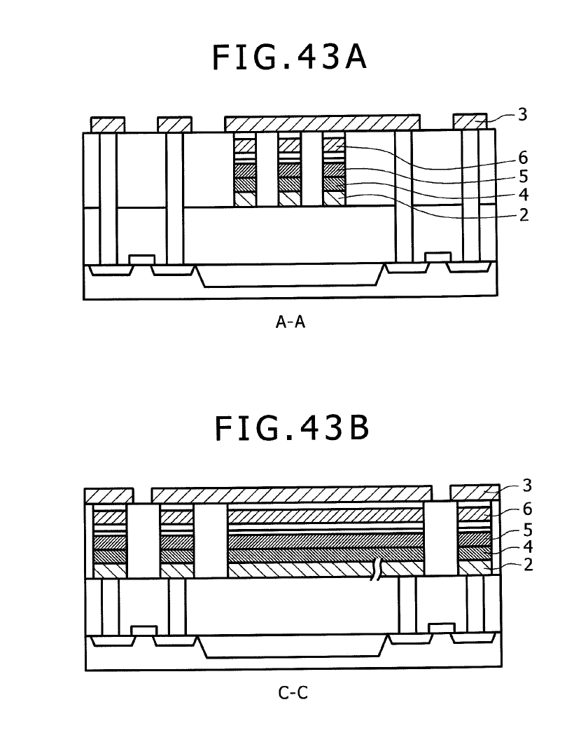

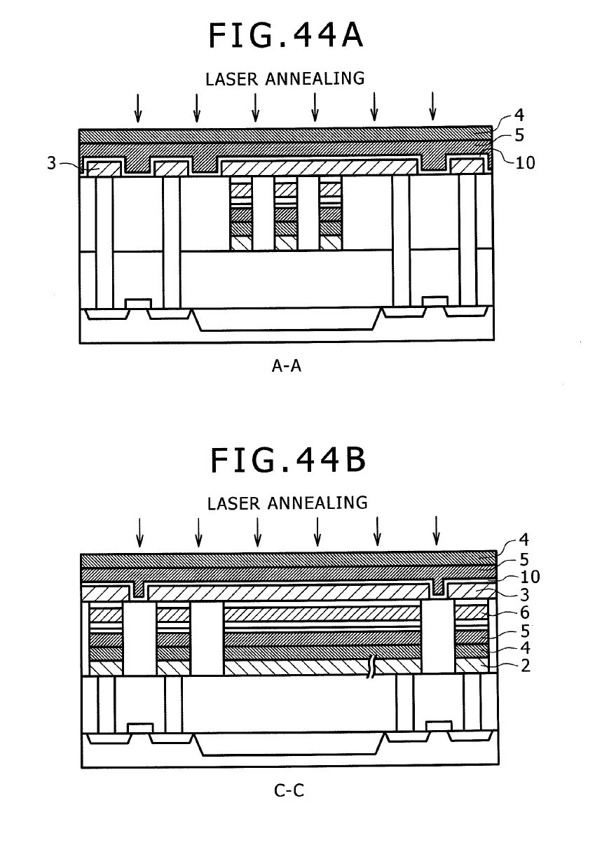

Next, the bit line material is patterned, such that it becomes as shown in FIGS. 42 and 43A and 43B. Subsequently, the silicide 10, such as WSi, TiSi₂, is formed and the P-doped amorphous silicon 15 and the amorphous silicon 11 on which the impurities are not doped are deposited. Subsequently, the B ions are doped to the amorphous silicon 11 by the ion implantation method and then, the crystallization of the amorphous silicon 14 and 15 and the activation of the impurities are performed by, for example, the CO₂ laser annealing (FIGS. 44A and 44B).

Laser annealing sufficiently performs the crystallization of the amorphous silicon and the activation of the impurities and is performed to make the current drivability of the diode, which becomes the selection device, sufficient and to reduce the thermal load to the phase change memory material 6 configuring the memory array in the first layer, while not reducing the yield.

Generally, in order to crystallize the polysilicon using the furnace body, there is a need to perform the heat treatment at a temperature of 700° C. or more for a long time. Meanwhile, the yield of the phase change device is reduced to approximately 0% due to the thermal load. If the annealing is performed within a short time by laser annealing in a state where there is the bit line material 3 between the phase change material 6 and the amorphous silicon of the second layer subjected to the crystallization, it is possible to suppress the temperature increase of the phase change material 6 and to reduce the thermal load when the amorphous silicon of the second layer is crystallized, as compared to a case of furnace body heating.

When crystallizing the amorphous silicon by laser annealing, the laser is not irradiated on the entire semiconductor main plane at the same time, but irradiated on a part thereof several times. At this time, if the bit line material 3 that becomes the metal film is connected to the entire semiconductor main plane, heat from the laser irradiating part is transferred to the bit line material 3 and heat-dissipated, such that a high laser power is needed for the crystallization. The crystallization of the amorphous silicon and the activation of the impurities can be achieved with a small laser power by patterning the metal film just below the amorphous silicon subjected to the crystallization according to the second embodiment.

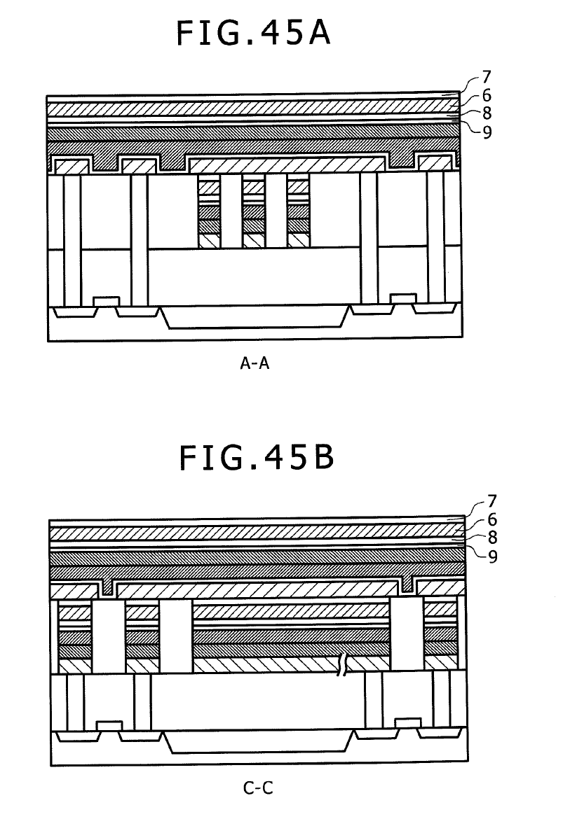

Next, the silicide 9, such as WSi, TiSi₂, is formed on the surface of the B-doped polysilicon 4 and reference numeral 8 (TiN, W, and the like) that becomes the lower electrode of the phase change device, the phase change material 6 (Ge₂Sb₂Te₅, and the like), reference numeral 7 (TiN, W, and the like) that becomes the upper electrode of the phase change device are sequentially deposited (FIG. 45). Further, the staked PN diode structure by the polysilicon can also be formed by methods other than the method shown in FIG. 44.

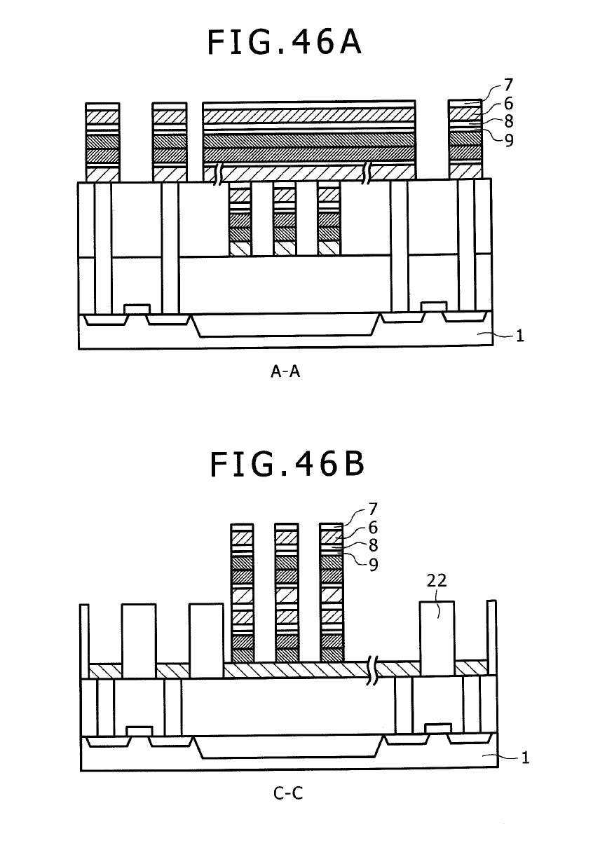

As described in the first embodiment, the first method (FIGS. 22A and 22B), the second method (FIGS. 22C and 22D), the third method (FIGS. 23A to 23D), the fourth method (FIGS. 24A to 24C), and the fifth method (FIGS. 25A to 25C) among other methods can be used on the patterned bit line 3. Subsequently, the upper electrode 7, the phase change material 6, the lower electrode 8, the silicide 9, the B-doped polysilicon 4, the P-doped polysilicon 5, the silicide 10, the bit line material 3, the upper electrode 7 of the memory array in the first layer, the phase change material 6 of the memory array in the first layer, the lower electrode 8 of the memory array in the first layer, the silicide 10 of the memory array in the first layer, the P-doped polysilicon 5 of the memory array in the first layer, and the B-doped polysilicon 4 of the memory array in the first layer are patterned in a stripe shape that extends in a y direction. At this time, a pattern is left in a portion in which the contact hole reaching BL and GBL is formed (FIGS. 46A and 46B). The memory array in the second array is patterned in a stripe shape, such that the cross point structure of the memory array in the first layer is completed.

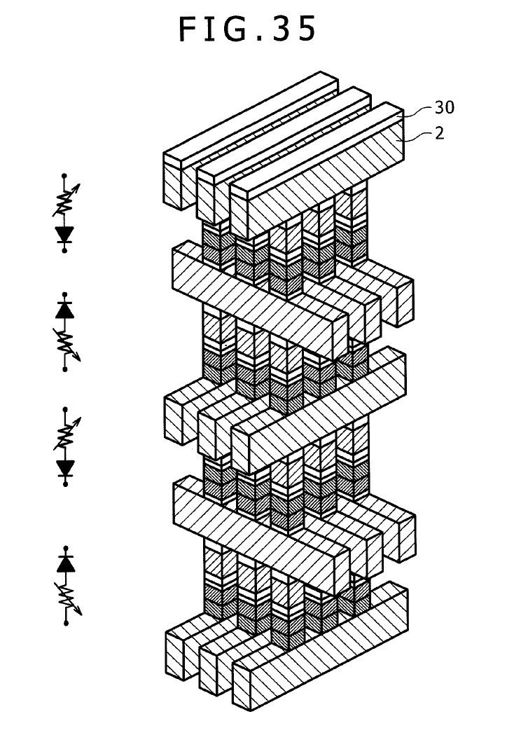

Hereinafter, like the processes from FIG. 29 to FIG. 35 of the first embodiment, the semiconductor memory device is manufactured by performing the patterning process only each time the bit line or the word line is deposited. Like the case of the first embodiment, if the semiconductor memory device is manufactured by the method according to the related art performing the polysilicon crystallization of the transistor, which becomes the selection device, by the furnace body heating, it is impossible to achieve both the current drivability of the selection device of the stacked phase change memory and yield Ymin or more of the phase change device. According to the method of the present invention, it is possible to achieve both as well as reducing costs of the phase change memory and to make capacity of the phase change memory large due to the stacking. In the second embodiment, although the variable resistance element becomes the phase change memory and the transistor that becomes the selection device is formed of the polysilicon, the variable resistance element can be formed of ReRAM, such as NiO, CuO, TiO₂, and the selection transistor can be formed of semiconductor other than silicon, such as Ge, SiGe. Even in using the same method as above, the same effect can be obtained.

### Third Embodiment

In the second embodiment, although the bit line material and the word line material are patterned and then, the amorphous silicon 14, 11, and 15, the silicides 9 and 10, the lower electrode 7, the phase change material 6, and the upper electrode 8 are deposited on the non-smoothed surface, as described in the third embodiment, a step caused in performing the lithography and the dry etching is small and the working can be easily performed, by performing the smoothness and then depositing the above-mentioned films. After performing the process of FIG. 37 of the second embodiment, the insulating film 31 is buried so that the word line 2 is completely buried and a portion of the insulating film 31 is removed by the CMP to expose the upper surface of the word line 2. Thereafter, through the process of the third embodiment, the semiconductor memory device is completed by performing the burying of the bit line and the word line by the insulating film and the smoothness of the surface, only each time the bit line and the word line are patterned.

Like the first and second embodiments, if the semiconductor memory device is manufactured according to the method of the related art performing the polysilicon crystallization of the transistor that becomes the selection device by the furnace body heating, it is impossible to achieve both the current drivability of the selection device of the stacked phase change memory and yield Ymin or more of the phase change device. According to the method of the present invention, it is possible to achieve both as well as to reduce costs of the phase change memory and to make capacity of the phase change memory large due to the stacking.

In the third embodiment, although the variable resistance element becomes the phase change memory and the transistor that becomes the selection device is formed of the polysilicon, the variable resistance element can be formed of ReRAM, such as NiO, CuO, TiO₂, and the selection transistor can be formed of semiconductor other than silicon, such as Ge, SiGe. Even in using the same method as above, the same effect can be obtained.

### Fourth Embodiment

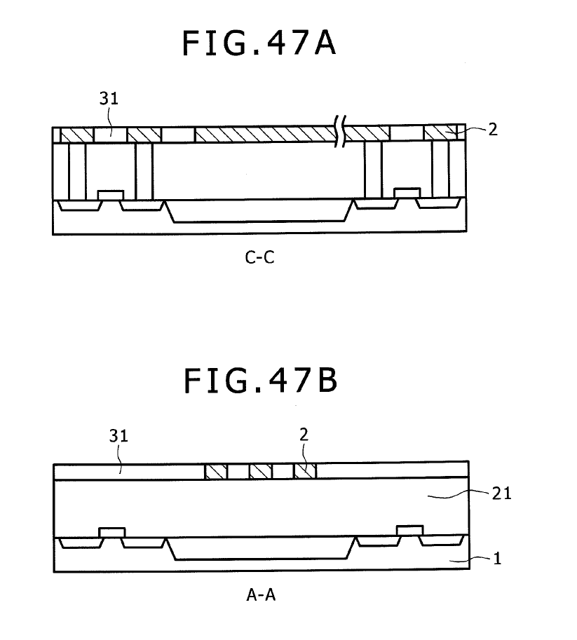

In the first to third embodiments, although the memory array is formed by only performing the mask in the stripe shape in the x and y directions, the memory array can also be formed by adding a mask in a pillar shape forming the memory cell as described in a fourth embodiment. FIGS. 47 to FIG. 61 show a method of manufacturing a semiconductor memory device according to the fourth embodiment.

First of all, like the first embodiment, the selection transistor ST is formed on the silicon substrate by using the known technology. The device on the silicon substrate formed with the peripheral circuits necessary for driving the memory array is also formed similar to the above-mentioned device.

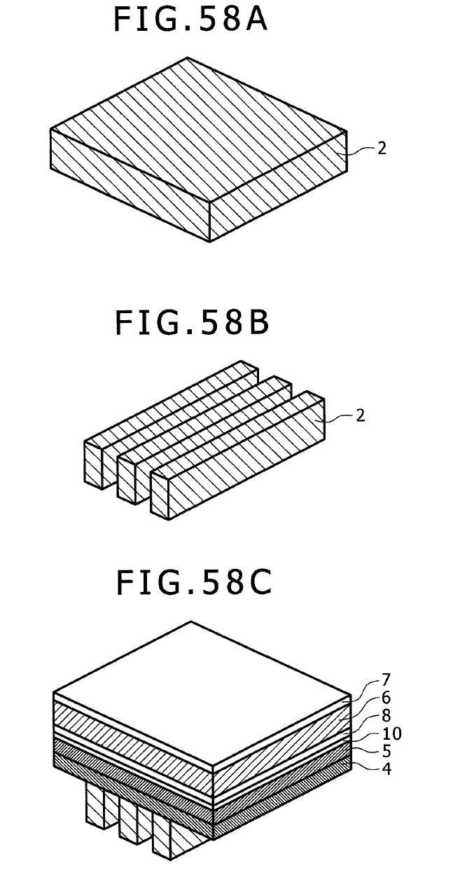

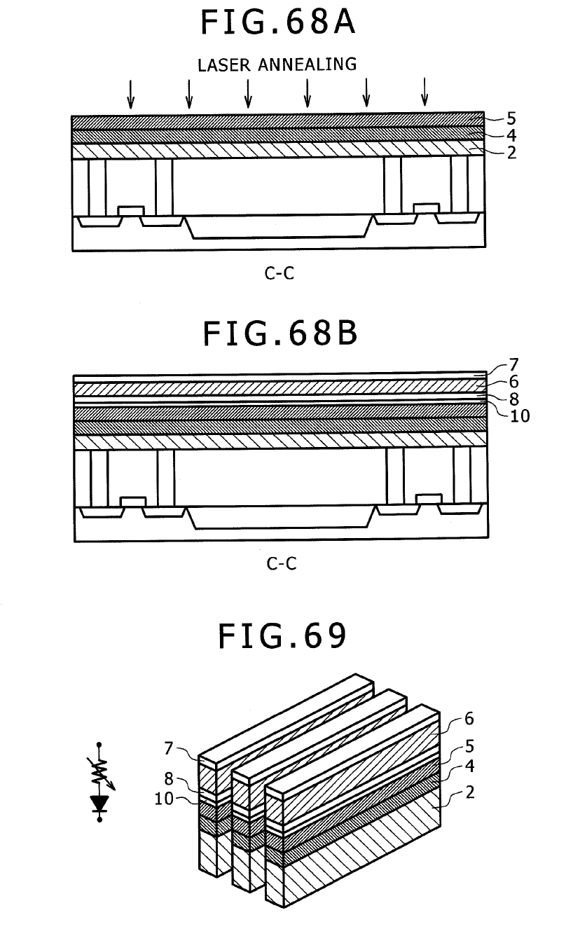

Next, tungsten 2 as one example that becomes the word line material is deposited by the sputtering method, for example. The deposition temperature of tungsten is 200° C. or less. Next, the word line 2 is processed so that it has the same pattern as FIG. 68, buried in the insulating film 31, and then smoothed by the CMP (FIGS. 47A and 47B). A cubic diagram thereof is shown in FIG. 58B from FIG. 58A by patterning the word line.

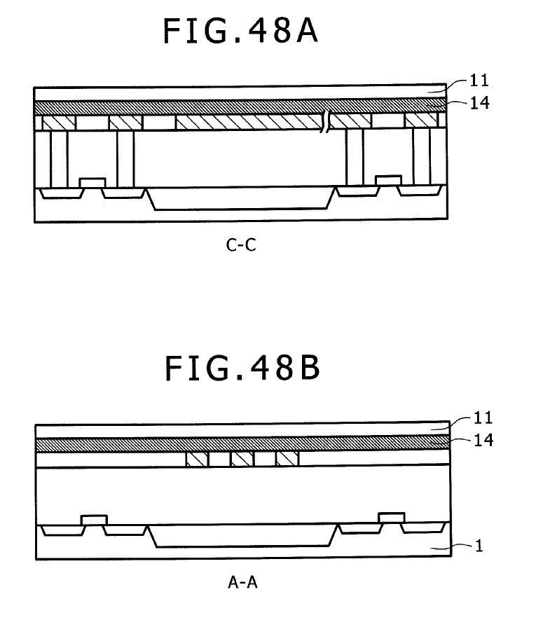

Then, the B-doped amorphous silicon 14 and the amorphous silicon 11 on which the impurities are not doped are deposited (FIGS. 48A and 48B). The CVD method is used to deposit the B-doped amorphous silicon 14 and the amorphous silicon 11 on which the impurities are not doped. The deposition temperature of the B-doped amorphous silicon is about 400° C. and the deposition temperature of the amorphous silicon 11 on which the impurities are not doped is about 530° C.

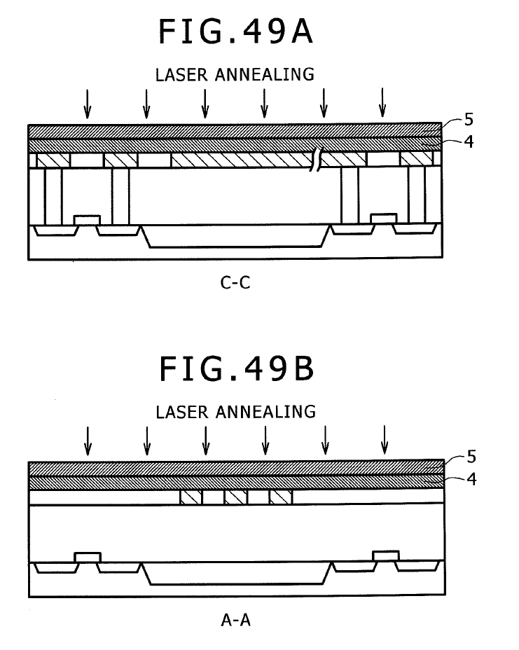

Subsequently, the phosphorus ions are doped to the amorphous silicon 11 by the ion implantation method and then, the crystallization of the amorphous silicon 14 and 15 and the activation of the impurities are performed by, for example, the CO₂ laser annealing (FIG. 49). At this time, since the phase change memory material is not included, it is not necessary to perform laser annealing that is performed to reduce the thermal load, but it is possible to perform the crystallization of the polysilicon and the activation of the impurities by the general heating furnace. However, when the memory array following the second layer is manufactured as described below, laser annealing should be performed without exception. In the fourth embodiment, since the selection devices following the first layer and the second layer have the same characteristics, the same laser annealing as one used following the second layer in the process of FIG. 49 is used.

Further, since the word line material is patterned, the crystallization of the amorphous silicon 14 and 15 and the activation of the impurities can be performed using small laser power similar to the second and third embodiments. Next, the silicide 10, such as WSi, TiSi₂ is formed on the surface of the P-doped polysilicon 5 and reference numeral 8 (TiN, W, and the like) that becomes the lower electrode of the phase change device, the phase change material 6 (Ge₂Sb₂Te₅, and the like), reference numeral 7 (TiN, W, and the like) that becomes the upper electrode of the phase change device are sequentially deposited. FIG. 58C shows a cubic diagram thereof.

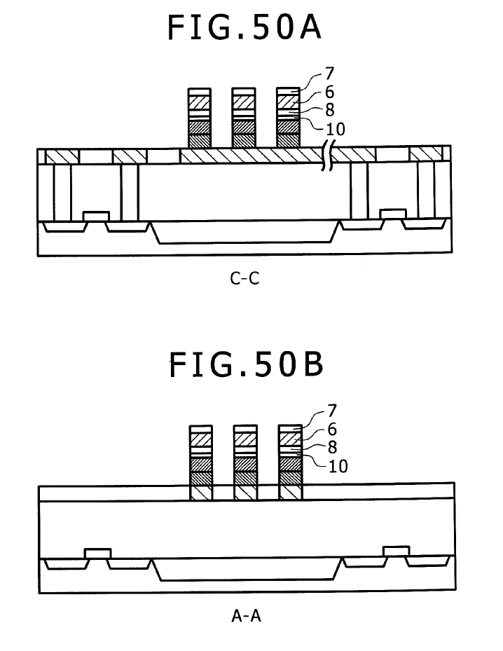

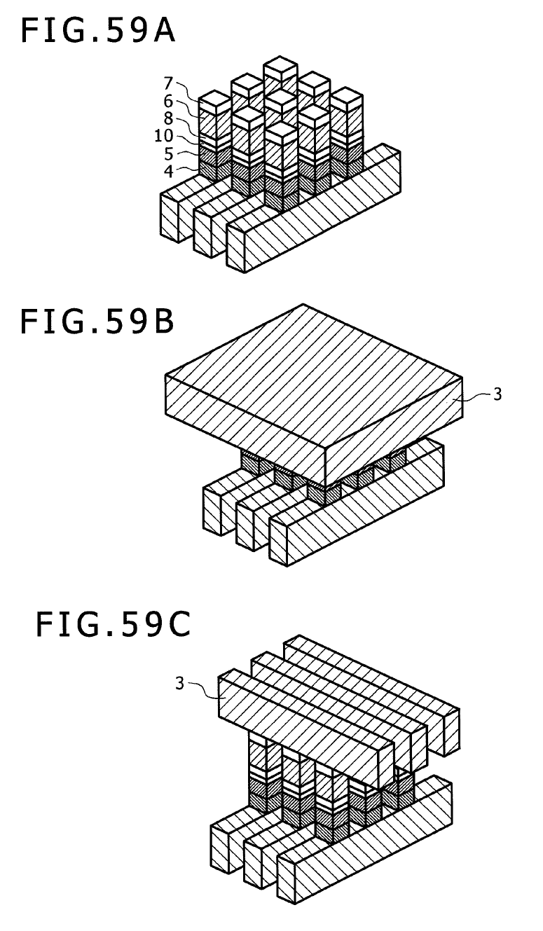

The stacked diode structure by the polysilicon can be formed by methods other than the methods shown in FIGS. 48 and 49. As described in the first embodiment, the first method (FIGS. 12A and 12B), the second method (FIGS. 12C and 12D), the third method (FIGS. 13A to 13D), the fourth method (FIGS. 14A to 14C), and the fifth method (FIGS. 15A to 15C) among other methods can be used on the patterned word line 2. Subsequently, the upper electrode 7, the phase change material 6, the lower electrode 8, the silicide 10, the P-doped polysilicon 5, the B-doped polysilicon 4, and the word line material 2 are patterned in a pillar shape. At this time, there is a need to match patterns so that the pillar structure is formed on WL (FIGS. 50A and 50B). FIG. 59A shows a cubic diagram thereof.

Next, the silicon oxide film 22 is deposited by, for example, the CVD method and in FIGS. 50A and 50B, a patterned space is completely buried. Subsequently, the upper electrode 7 whose surface is smoothed by, for example, the CMP method is exposed. Then, after the contact hole reaching the diffusion layer of the selection transistor connected to the bit line is formed and W is buried in, for example, the contact hole 150 by, for example, the CVD method, W deposited on the upper surface is removed by the CMP method, thereby forming the plug. Thereafter, the material (for example, tungsten) that becomes the bit line material 3 is deposited. FIG. 59B shows a cubic diagram thereof.

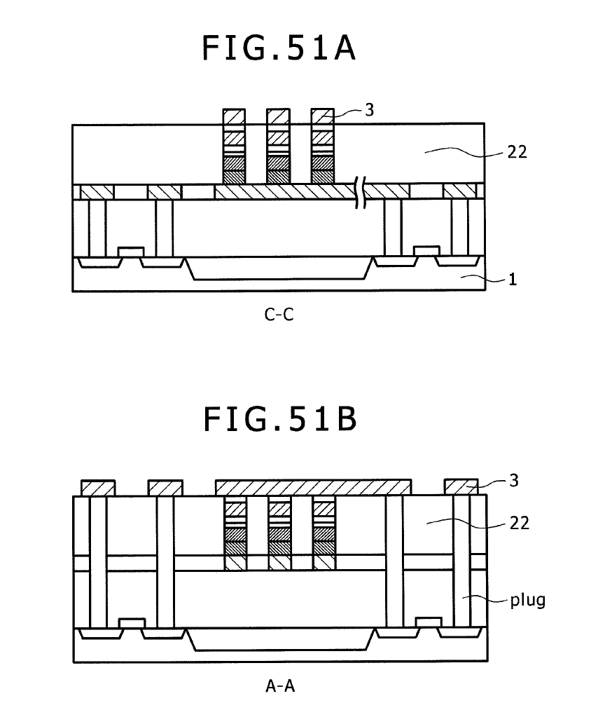

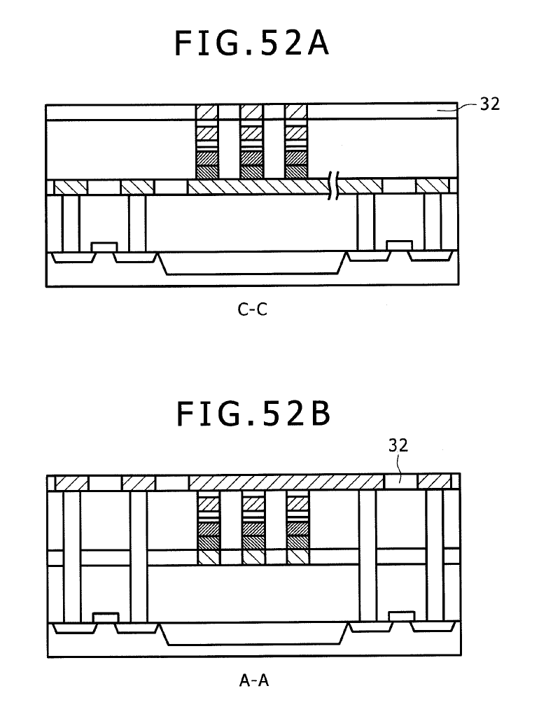

Next, the bit line material is patterned in the stripe shape that extends in the y direction. There is a need to form the bit line by matching patterns so that it exists on the pillar structure of the memory cell (FIGS. 51A and 51B). Further, at this time, the pattern is left in a portion in which the contact hole reaching BL and GBL is formed. The cross point structure of the memory array in the first layer is completed. FIG. 59C shows a cubic diagram thereof. Subsequently, after the processed bit line is buried in the insulating film 32 and smoothed by the CMP (FIGS. 52A and 52B).

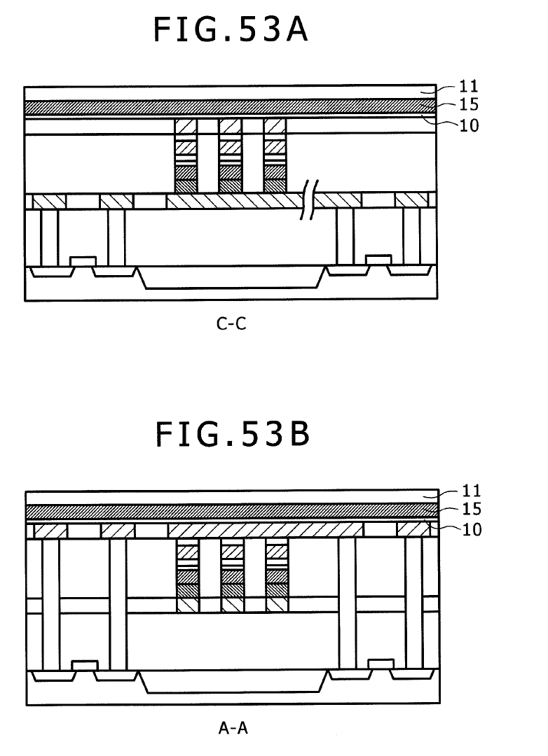

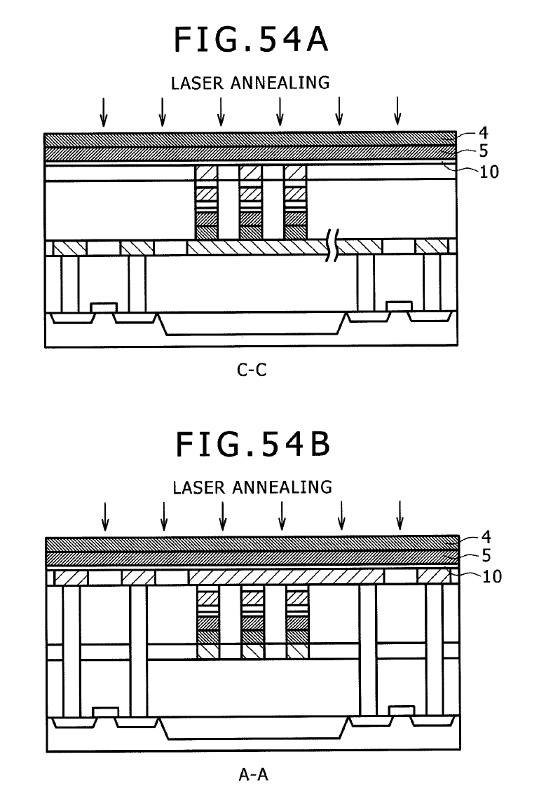

Then, the silicide 10, such as WSi, TiSi₂, is formed and the P-doped amorphous silicon 15 and the amorphous silicon 11 on which the impurities are not doped are deposited (FIGS. 53A and 53B). Thereafter, the B ions are doped to the amorphous silicon 11 by the ion implantation method and then, the crystallization of the amorphous silicon 14 and 15 and the activation of the impurities are performed by, for example, CO₂ laser annealing (FIGS. 54A and 54B).

Laser annealing sufficiently performs the crystallization of the amorphous silicon and the activation of the impurities and is performed to make the current drivability of the diode, which becomes the selection device, sufficient, and to reduce the thermal load to the phase change memory material 6 configuring the memory array of the first layer while not reducing the yield

Generally, in order to crystal the polysilicon by the furnace body, there is a need to perform the heat treatment at a temperature of 700° C. or more for a long time. Meanwhile, the yield of the phase change device is reduced to approximately 0% due to the thermal load. If annealing is performed in a short time by laser annealing in a state where the bit line material 3 is between the phase change material 6 and the amorphous silicon of the second layer subjected to the crystallization, it is possible to suppress the temperature increase of the phase change material 6 and to reduce the thermal load when the amorphous silicon of the second layer is crystallized and, as compared to a case of furnace body heating.

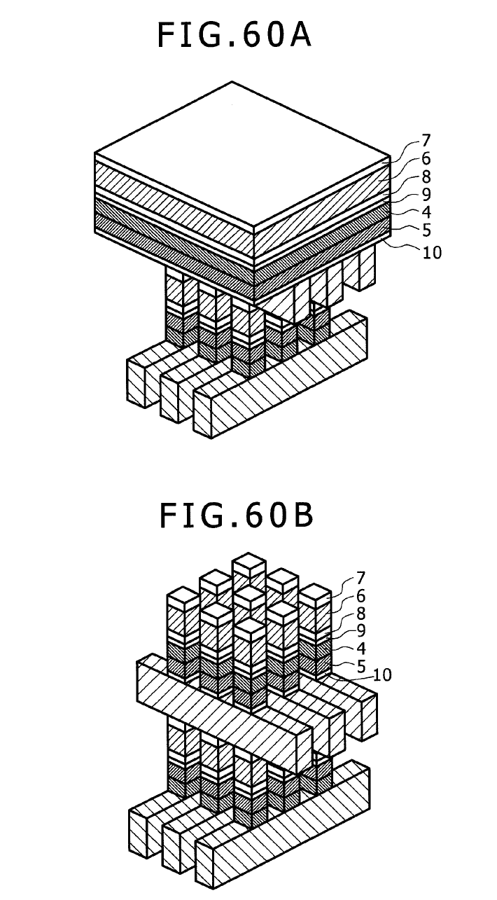

Further, since the word line material is patterned, the crystallization of the amorphous silicon 14 and 15 and the activation of the impurities can be performed using small laser power similar to the second and third embodiments. Next, the silicide 9, such as WSi, TiSi₂ is formed on the surface of the B-doped polysilicon 4 and reference numeral 8 (TiN, W, and the like) that becomes the lower electrode of the phase change device, the phase change material 6 (Ge₂Sb₂Te₅, and the like), reference numeral 7 (TiN, W, and the like) that becomes the upper electrode of the phase change device are sequentially deposited. FIG. 60A shows a cubic diagram thereof.

The stacked PN diode structure by the polysilicon can be formed by methods other than the methods shown in FIGS. 53 and 54. As described in the first embodiment, the first method (FIGS. 22A and 22B), the second method (FIGS. 22C and 22D), the third method (FIGS. 23A to 23D), the fourth method (FIGS. 24A to 24C), and the fifth method (FIGS. 25A to 25C) among other methods can be used on the patterned bit line 3. Subsequently, the upper electrode 7, the phase change material 6, the lower electrode 8, the silicide 9, the B-doped polysilicon 4, and the P-doped polysilicon 5 are patterned in a pillar structure. At this time, there is a need to match patterns so that the pillar structure is formed on BL. FIG. 60B shows a cubic diagram thereof.

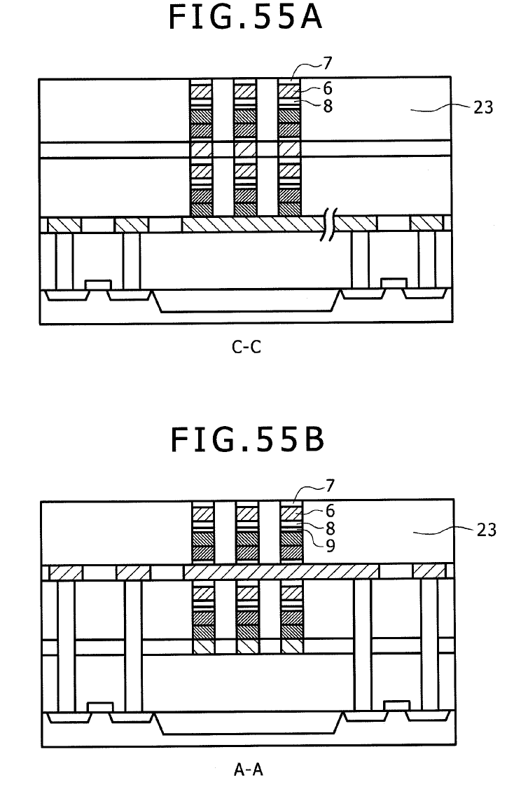

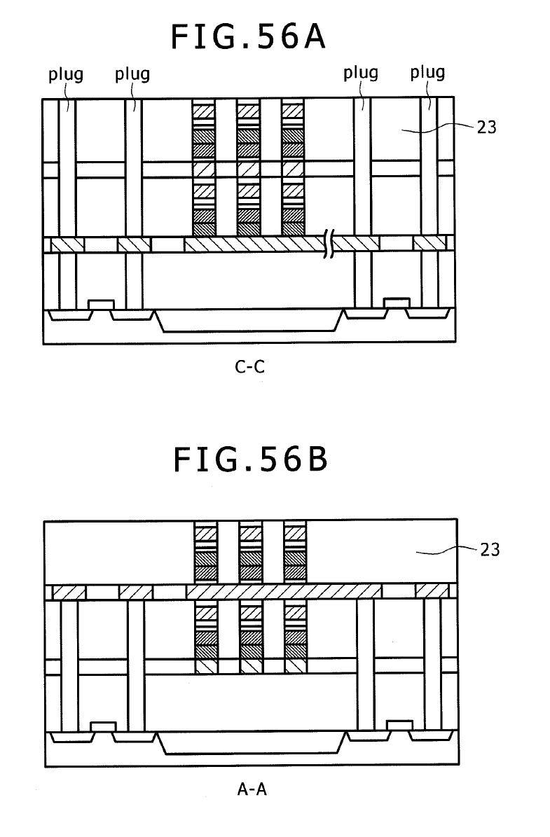

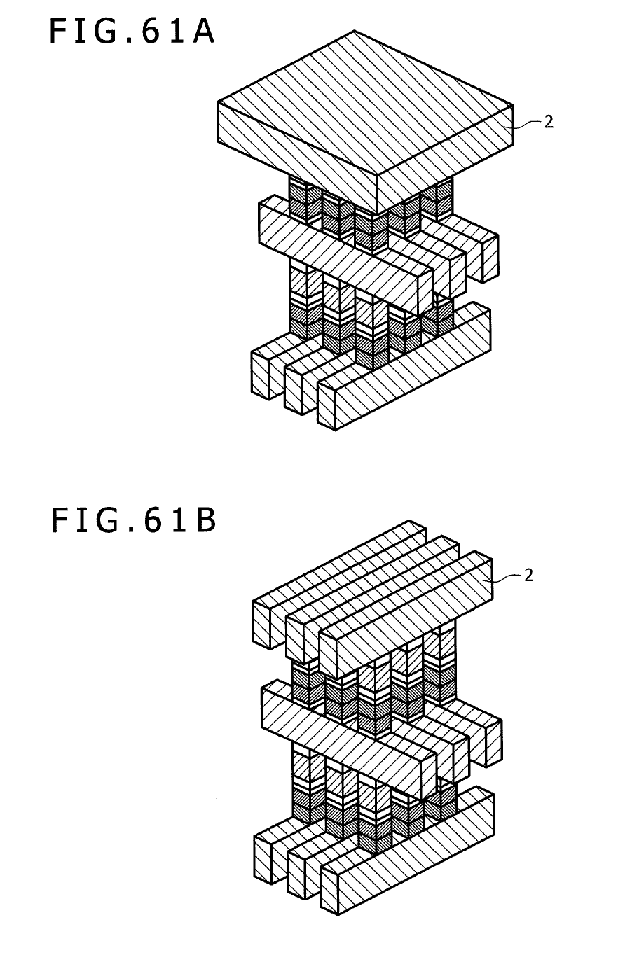

Next, the silicon oxide film 23 is deposited by, for example, the CVD method and in FIG. 60B, the patterned space is completely buried. Subsequently, the upper electrode 7 whose surface is smoothed by, for example, the CMP method is exposed (FIGS. 55A and 55B). Subsequently, after the contact hole reaching the word line in the first layer is formed and W is buried in, for example, the contact hole by, for example, the CVD method, W deposited on the upper surface is removed by, for example, the CMP method, thereby forming the plug (FIGS. 56A and 56B). Thereafter, the material (for example, tungsten) that becomes the word line material 2 is deposited. FIG. 61A shows a cubic diagram thereof.

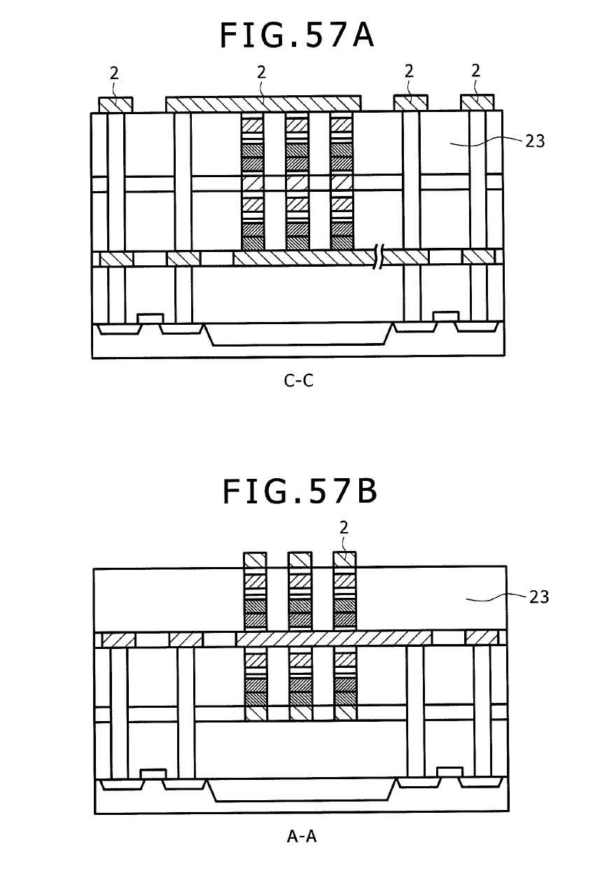

Next, the word line material is patterned in the stripe shape that extends in the y direction. There is a need to match patterns so that the word line exists in on the pillar structure of the memory cell (FIGS. 57A and 57B). FIG. 61B shows a cubic diagram thereof. Further, at this time, the pattern is left in a portion in which the contact hole reaching BL and GBL is formed. The cross point structure of the memory array in the second layer is completed.

Hereinafter, the array of the third layer and the fourth layer can be formed by repeating the above-mentioned process. Like the case of the first to fourth embodiments, if the semiconductor memory device is manufactured by the method according to the related art performing the polysilicon crystallization of the transistor that becomes the selection device by the furnace body heating, it is impossible to achieve both the current drivability of the selection device of the stacked phase change memory and yield Ymin or more of the phase change device. According to the method of the present invention, it is possible to achieve both as well as to reduce costs of the phase change memory and to make capacity of the phase change memory large due to the stacking.

In the fourth embodiment, although the variable resistance element becomes the phase change memory and the transistor that becomes the selection device is formed of the polysilicon, the variable resistance element may be formed of ReRAM, such as NiO, CuO, TiO₂, and the selection transistor may be formed of semiconductor other than silicon, such as Ge, SiGe. Even in using the same method as above, the same effect can be obtained

### Fifth Embodiment

In the first to fourth embodiment, although the method of manufacturing the cross point cell array that commonly uses the word line and the bit line in the neighboring memory array layer, it is possible to independently form the word line and the bit line for each memory array layer as described in the fifth embodiment.

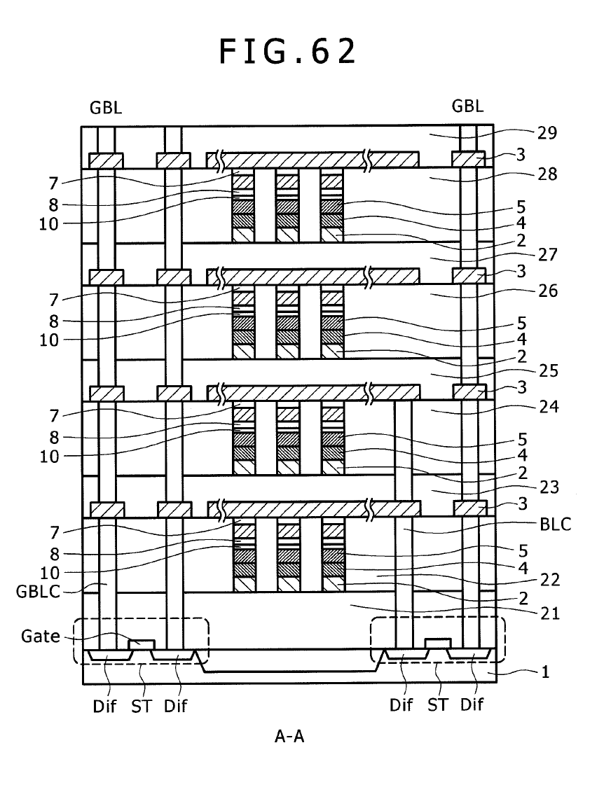

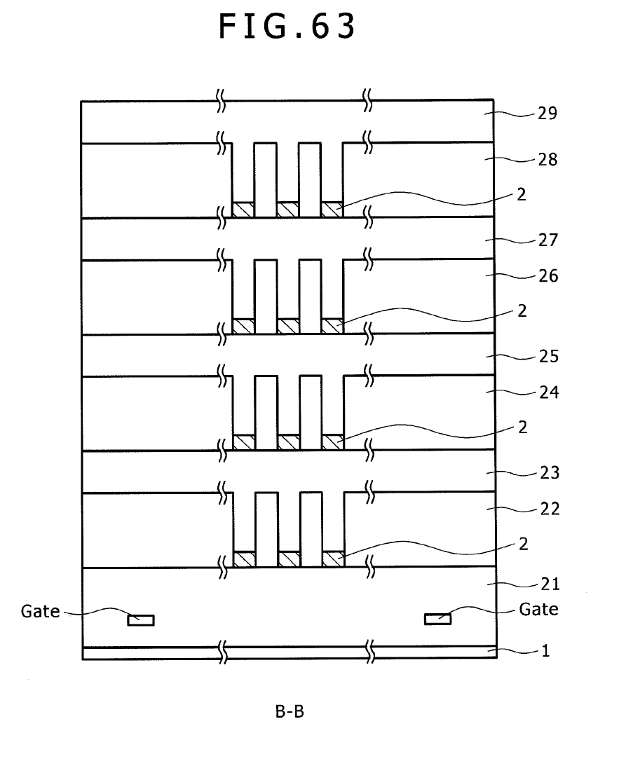

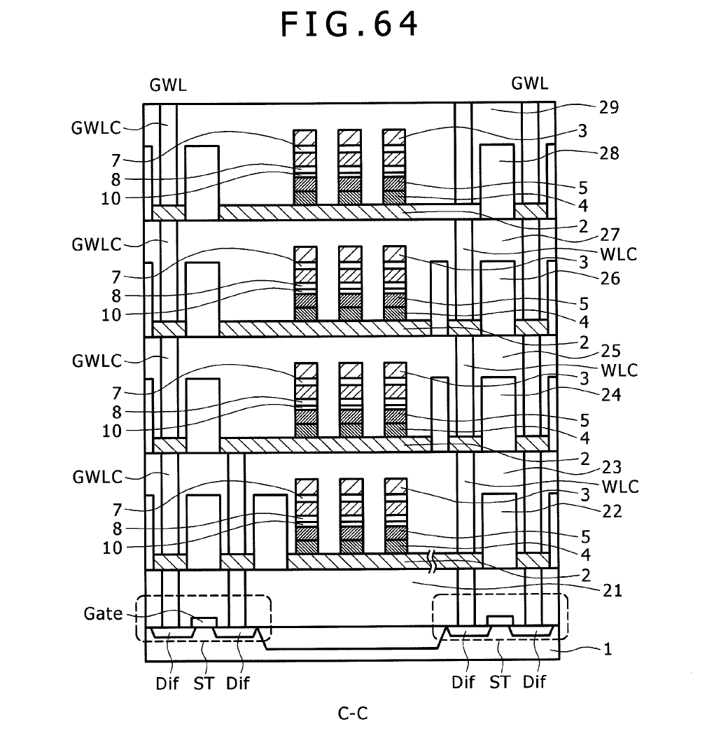

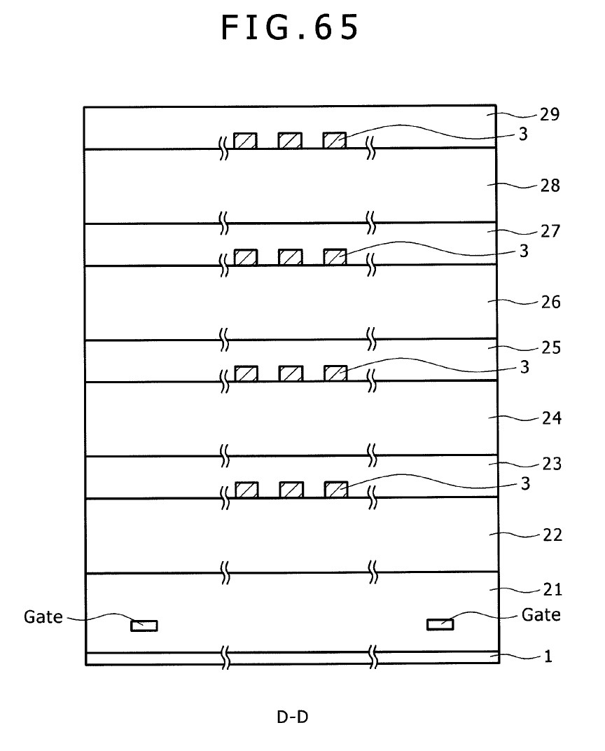

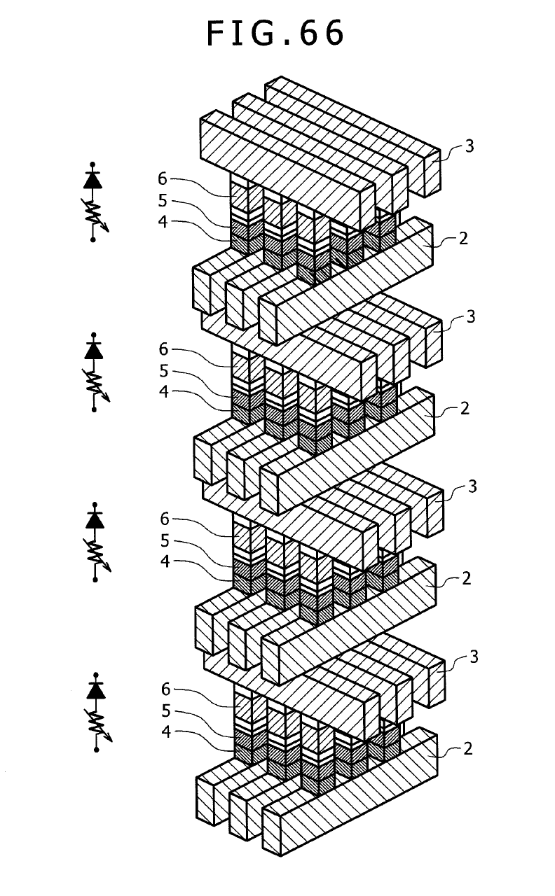

FIG. 1 is a plan view of the semiconductor memory device according to the fifth embodiment, which is the same as the first to fourth embodiments. FIGS. 62 to 65 are cross sectional views taken along the line A-A, line B-B, line C-C, and line D-D in FIG. 1. Further, FIG. 66 is a cubic diagram showing only the memory array part. Moreover, in the plane view of FIG. 1 and the cubic diagram of FIG. 66, parts of the components are omitted to make the drawings easy to see.

The semiconductor memory device according to the fifth embodiment is the same as the first to fourth embodiments in that the phase change memory that becomes the variable resistance element is used as the memory device, and the polysilicon diode is used as the selection device and they form the array in the stacked cross point type. However, it does not commonly use the word line and the bit line in the neighboring memory array layer. For this reason, there is no need to make the polarity of the diode that becomes the selection device into a reverse direction in the neighboring memory layer, thus the polarity thereof may be set in the same direction (FIG. 66).

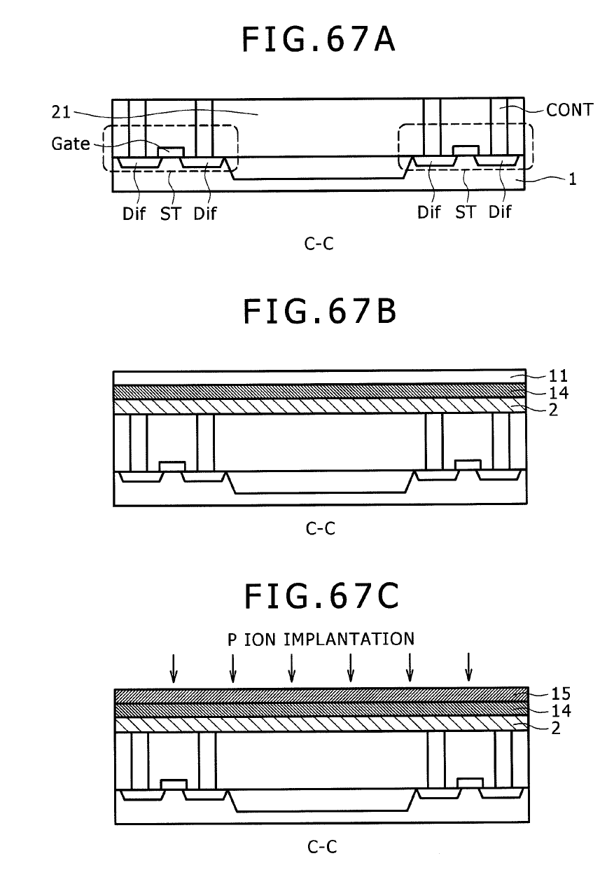

Although FIGS. 62 to 66 show the memory array in the case where four layers are stacked, it is of course possible to stack five layers or more. The operation of the phase change device is the same as described in FIG. 7. Further, the cell selecting scheme within the memory array when performing the reading and set/reset is the same as one described in FIGS. 8 and 9. Next, the method of manufacturing the stacked phase change memory will be described with reference to FIGS. 67 to 74. The ST and the device of the peripheral circuit are buried in the insulating film 21 after forming the ST and if necessary, one smoothing the surface by the chemical mechanical polishing method (CMP method) is the same as a state of FIG. 67A. Next, the tungsten 2 as one example that becomes the word line, the B-doped amorphous silicon 14, the amorphous silicon 11 on which the impurities are not doped are deposited (FIG. 67B). The sputtering method is used to deposit the tungsten 2 and the CVD method is used to deposit the B doped amorphous silicon 14 and the amorphous silicon 11 on which the impurities are not doped. The deposition temperature of tungsten is 200° C. or less, the deposition temperature of the B doped amorphous silicon is about 400° C., and the deposition temperature of the amorphous silicon 11 on which the impurities are not doped is about 530° C. Subsequently, the phosphorus ions are doped to the amorphous silicon 11 by then ion implantation method (FIG. 67C).

Next, the crystallization of the amorphous silicon 14 and 15 and the activation of the impurities are performed by, for example, CO₂ laser annealing (FIG. 68A). At this time, since the phase change memory material is not included, it is not necessary to perform laser annealing that is performed to reduce the thermal load, but it is possible to perform the crystallization of the polysilicon and the activation of the impurities using the general heating furnace. However, when the memory array following the second layer is manufactured as described below, laser annealing should be performed without exception. In the fifth embodiment, since the selection devices following the first layer and the second layer have the same characteristics, the same laser annealing as one used following the second layer in the process of FIG. 68A is used.

Next, the silicide 10, such as WSi, TiSi₂ is formed on the surface of the P-doped polysilicon 5 and reference numeral 8 (TiN, W, and the like) that becomes the lower electrode of the phase change device, the phase change material 6 (Ge₂Sb₂Te₅, and the like), reference numeral 7 (TiN, W, and the like) that becomes the upper electrode of the phase change device are sequentially deposited (FIG. 68B). The stacked PN diode structure by the polysilicon is stacked can be formed by methods other than the methods shown in FIGS. 67 and 68.

As described in the first embodiment, the first method (FIGS. 12A and 12B), the second method (FIGS. 12C and 12D), the third method (FIGS. 13A to 13D), the fourth method (FIGS. 14A to 14C), and the fifth method (FIGS. 15A to 15C) among other methods can be used.

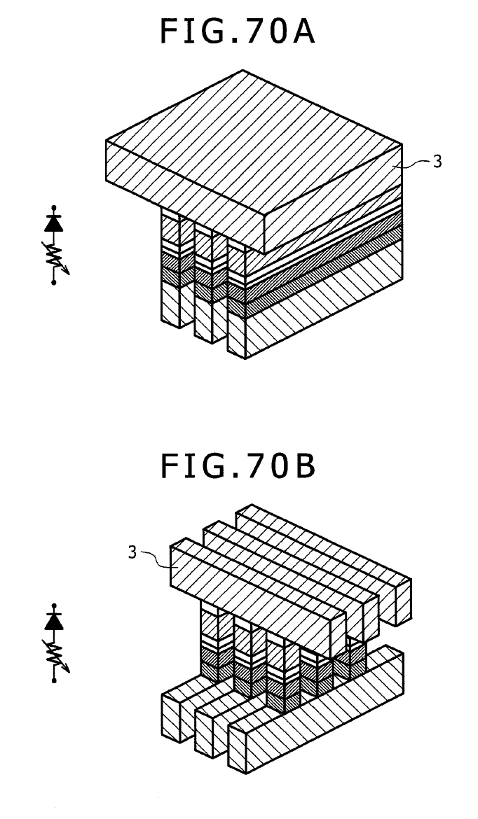

Subsequently, as shown in FIG. 68B, the upper electrode 7, the phase change material 6, the lower electrode 8, the silicide 10, the P-doped polysilicon 5, the B-doped polysilicon 4, and the word line material 2 are patterned in the stripe shape that extends in an x direction. At this time, the pattern is left in a portion in which the contact hole reaching WL and GWL is formed. FIG. 69 shows a cubic diagram of the memory array part. Next, the silicon oxide film 22 is deposited by, for example, the CVD method and in FIG. 69, the patterned space is completely buried. Subsequently, the upper electrode 7 whose surface is smoothed by, for example, the CMP method is exposed. Then, the contact hole 150 reaching the diffusion layer of the selection transistor connected to the bit line is formed. Next, W is buried in, for example, the contact hole 150 by, for example, the CVD method or Ti, TiN, or W is sequentially buried in, for example, the contact hole 150 by the CVD method, for example. W deposited on the upper surface is removed by the CMP method, thereby forming the plug and then the material that becomes the bit line 3 is deposited. FIG. 70B shows a cubic diagram thereof. Subsequently, the bit line material, the upper electrode 7, the phase change material 6, the lower electrode 8, the silicide 10, the P-doped polysilicon 5, and the B-doped polysilicon 4 are patterned in the stripe shape that extends in the y direction. Further, at this time, the pattern is left in a portion in which the contact hole reaching the BL and GBL is formed. The cross point structure of the memory array in the first layer is completed (FIG. 70B). Next, the insulating film 23 to separate the memory array layer, the first layer, and the second layer is deposited and then, the upper surface of the insulating film 23 is smoothed by the CMP. Subsequently, the contact hole reaching the word line of the first layer is formed. Subsequently, W is buried in, for example, the contact hole by, for example, the CVD method or Ti, TiN, and W are sequentially buried in, for example, the contact hole by, for example, the CVD method. W deposited on the upper surface is removed by, for example, the CMP method, thereby forming the plug.

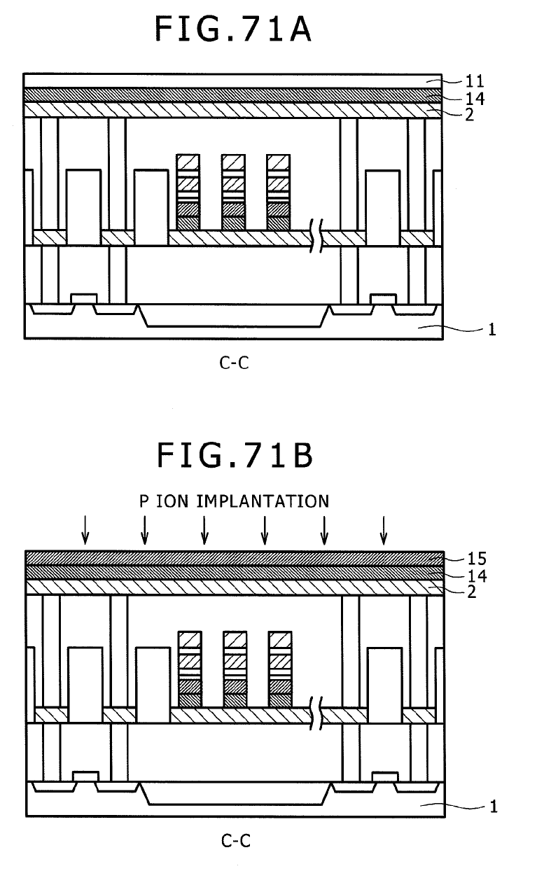

Then, the tungsten 2, as an example, that becomes the word line, the B-doped amorphous silicon 14, and the amorphous silicon 11 on which the impurities are not doped are deposited (FIG. 71A). The sputtering method is used to deposit the tungsten 2, the CVD method is used to deposit the B-doped amorphous silicon 14 and the amorphous silicon 11 on which the impurities are not doped. The deposition temperature of tungsten is 200° C. or less, the deposition temperature of the B-doped amorphous silicon is about 400° C. and the deposition temperature of the amorphous silicon 11 on which the impurities are not doped is about 530° C.

Thereafter, the phosphorus ions are doped to the amorphous silicon 11 by the ion implantation method (FIG. 71B) and then, the crystallization of the amorphous silicon 14 and 15 and the activation of the impurities are performed by, for example, CO₂ laser annealing (FIG. 72A). Laser annealing sufficiently performs the crystallization of the amorphous silicon and the activation of the impurities and is performed to make the current drivability of the diode, which becomes the selection device, sufficient and to reduce the thermal load to the phase change memory material 6 configuring the memory array of the first layer while not reducing the yield.

Generally, in order to crystal the polysilicon by the furnace body, there is a need to perform the heat treatment at a temperature of 700° C. or more for a long time. Meanwhile, the yield of the phase change device is reduced to approximately 0% due to the thermal load. If the annealing is performed in a short time by laser annealing in a state when there the bit line material 3 is between the phase change material 6 and the amorphous silicon of the second layer subjected to the crystallization, it is possible to suppress the temperature increase of the phase change material 6 and to reduce the thermal load when the amorphous silicon of the second layer is crystallized, as compared to a case of furnace body heating.

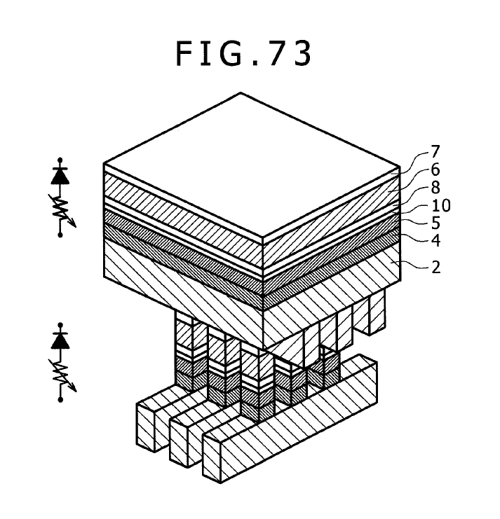

Next, the silicide 10, such as WSi, TiSi₂, is formed on the surface of the P-doped polysilicon 5 and reference numeral 8 (TiN, W, and the like) that becomes the lower electrode of the phase change device, the phase change material 6 (Ge₂Sb₂Te₅, and the like), reference numeral 7 (TiN, W, and the like) that becomes the upper electrode of the phase change device are sequentially deposited (FIG. 72B). FIG. 73 shows a cubic diagram thereof.

Hereinafter, the array of the second layer, the third array, and the fourth array can be formed by repeating the same process as one forming the first layer. Like the case of the first to fourth embodiments, if the semiconductor memory device is manufactured by the method according to the related art performing the polysilicon crystallization of the transistor that becomes the selection device by the furnace body heating, it is impossible to achieve both the current drivability of the selection device of the stacked phase change memory and yield Ymin or more of the phase change device. According to the method of the present invention, it is possible to achieve both as well as to reduce costs of the phase change memory and to make capacity of the phase change memory large due to the stacking. In the fifth embodiment, although the variable resistance element becomes the phase change memory and the transistor that becomes the selection device is formed of the polysilicon, the variable resistance element can be formed of ReRAM, such as NiO, CuO, TiO₂, and the selection transistor can be formed of semiconductor other than silicon, such as Ge, SiGe. Even in using the same method as above, the same effect can be obtained.

### Sixth Embodiment

In the first to fifth embodiments, although the diodes used for the selection device of the memory array are formed as a P-N diode or a P-I-N diode of the polysilicon, they can be formed as a Schottky diode between the polysilicon/metal.

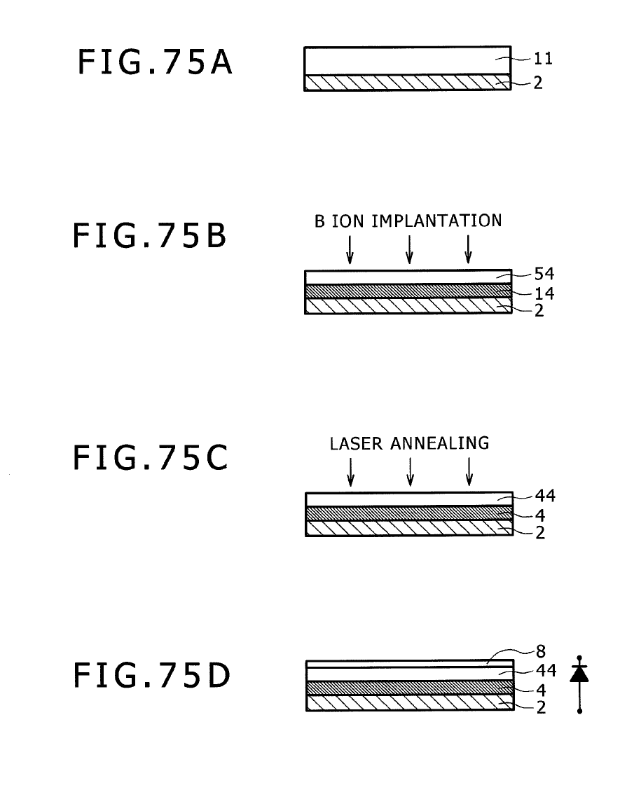

The Schottky diode can be formed using a method shown in FIGS. 75 to 78, for example. The amorphous silicon 11 on which the impurities are not doped is deposited, for example, on the tungsten that becomes the word line and the bit line (FIG. 75A). The sputtering method is used to deposit the tungsten 2 and the CVD method is used to deposit the amorphous silicon 11 on which the impurities are not doped. The deposition temperature of tungsten is 200° C. or less and the deposition temperature of the amorphous silicon 11 on which the impurities are not doped is about 530° C. Next, the B ions are doped to the amorphous silicon by the ion implantation method. The concentration of the impurity ions becomes high at the lower electrode side of the amorphous silicon, in particular, a surface side of the tungsten and becomes low at the surface side (FIG. 75B). Next, the amorphous silicon is crystallized by laser annealing (FIG. 75C) and the electrode 8 (for example, TiN) is deposited (FIG. 75D). According the above-mentioned process, the Schottky diode that defines as a forward a direction which makes a current flow upward can be formed.

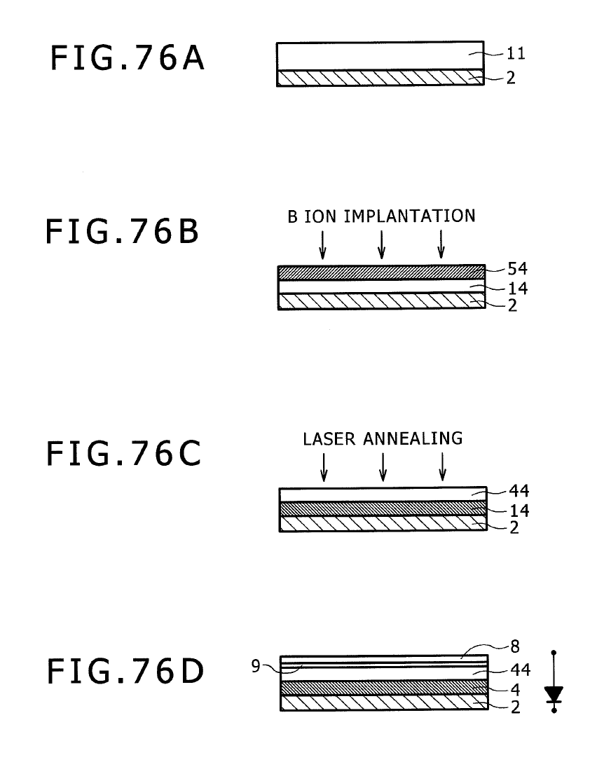

When the amorphous silicon 11 on which the impurities are not doped is deposited, for example, on the tungsten that becomes the word line and the bit line (FIG. 76A) and then the B ions are doped to the amorphous silicon by the ion implantation method, the concentration of the impurity ions becomes high at the upper surface of the amorphous silicon and becomes low at the lower electrode side (FIG. 76B). Next, after the amorphous silicon is crystallized by laser annealing (FIG. 76C), the silicide 9 is deposited and the electrode 8 (for example, TiN) is deposited (FIG. 76D). According the above-mentioned process, the Schottky diode that defines as a forward a direction that makes a current flow downward can be formed.

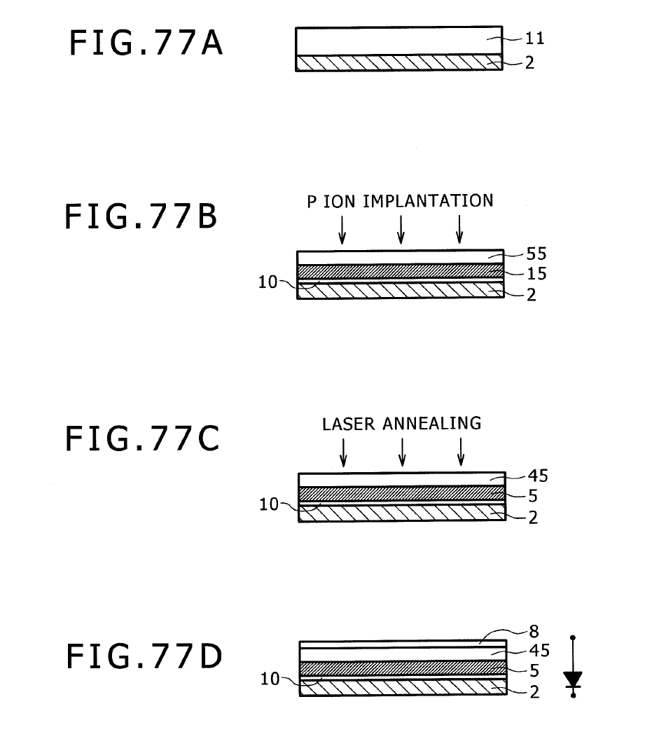

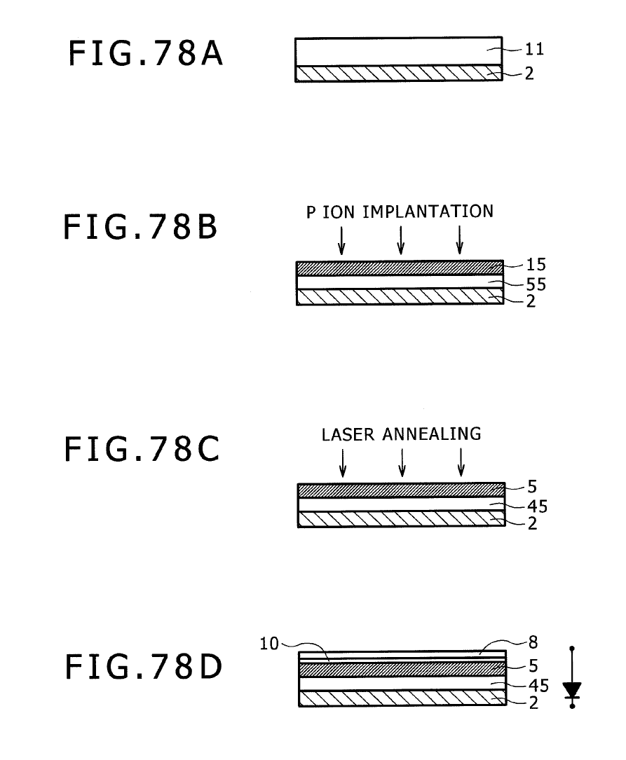

When the silicide 10 is deposited, for example, on the tungsten that becomes the word line and the bit line and the amorphous silicon 11 on which the impurities are not doped is deposited (FIG. 77A), the P ions are doped to the amorphous silicon by the ion implantation method, the concentration of the impurity ions becomes high at the lower electrode side of the amorphous silicon, in particular, the surface side of the tungsten and becomes low at the surface side (FIG. 77B). Next, after the amorphous silicon is crystallized by laser annealing (FIG. 77C), the electrode 8 (for example, TiN) is deposited (FIG. 77D). According the above-mentioned process, the Schottky diode that defines as a forward a direction that makes a current flow downward can be formed. After the word line and the bit line, in particular, the upper surface is formed of TiN and the amorphous silicon 11 on which the impurities are not doped is deposited (FIG. 78A), the P ions are doped to the amorphous silicon by the ion implantation method. The concentration of the impurity ions becomes high at the upper surface of the amorphous silicon and becomes low at the lower electrode interface (FIG. 78B). Next, after the amorphous silicon is crystallized by laser annealing (FIG. 78C), the silicide 10 and the electrode (for example, TiN) are deposited (FIG. 78D). According the above-mentioned process, the Schottky diode that defines as a forward a direction that makes a current flow upward can be formed.

Like the case of the first to fifth embodiments, if the semiconductor memory device using the Schottky diode of the manufacturing method of FIGS. 75 to 78 is manufactured according to the related art performing the crystallization of the polysilicon of the transistor that becomes the selection device by the furnace body heating, it is impossible to achieve both the current drivability of the selection device of the stacked phase change memory and yield Ymin or more of the phase change device. According to the method of the present invention, it is possible to achieve both as well as to reduce costs of the phase change memory and to make capacity of the phase change memory large by the stacking. In the sixth embodiment, although the variable resistance element becomes the phase change memory and the transistor that becomes the selection device is formed of the polysilicon, the variable resistance element may be formed of ReRAM, such as NiO, CuO, TiO₂, and the selection transistor may be formed of semiconductor other than silicon, such as Ge, SiGe. Even in using the same method as above, the same effect can be obtained.

### Seventh Embodiment

In the method of manufacturing the semiconductor memory device according to the first to sixth embodiments, the upper electrode 7 or the upper electrode 7 and the lower electrode 8 of the phase change material 6 can be formed of a material having thermal conductivity lower than that of the word line 2 and the bit line 3. When the crystallization of the polysilicon is performed by laser annealing according to the first to sixth embodiments, it is preferable that it is difficult to transfer heat from the polysilicon crystallized by laser annealing to the phase change material 6 so as to reduce the thermal load to the phase change material 6. It is preferable that becomes the word line 2, the bit line 3, the upper electrode 7, the lower electrode 8 are formed of metals having low thermal conductivity.

In the metal material, a Wiedemann-Franz law, that is, thermal conductivity÷electric conductivity=Lorenz number×absolute temperature is established. Where, the Lorenz number is 2.45×10⁻⁸ W ΩK⁻². Consequently, the metal having low thermal conductivity has the low electric conductivity and the metal having high thermal conductivity has low electricity conductivity. Since the word line 2 and the bit line 3 form a long wiring within the memory array that supplies a current in performing rewriting and reading of the phase change memory, if the electricity conductivity is not sufficiently high, a problem occurs that the phase change memory cannot be operated due to the voltage drop at the wiring, etc. To the contrary, the upper electrode 7 or the lower electrode 8 is short as the current path and is not necessary to have the high electric conductivity corresponding to the wiring.

Then, the thermal load during crystallization of the silicon by laser annealing can be reduced without increasing the negative influence on the operation of the phase change memory due to the wiring resistance, by forming the upper electrode 7 or both the upper electrode 7 and the lower electrode 8 with the material having thermal conductivity lower than that of the word line 2 and the bit line 3. In the manufacturing method according to the first to sixth embodiments, the metal having low thermal conductivity, such as TiN, is used for the upper electrode 7 and the lower electrode 8, and W, Cu, and the like are used for the word line 2 and the bit line 3, thereby making it possible to manufacture the non-volatile semiconductor memory device according to the seventh embodiment.

The non-volatile semiconductor memory device according to the present invention is suitably used for small-sized portable information devices, such as a portable personal computer, a digital still camera.

What is claimed is:

1. A method of manufacturing a semiconductor memory device having a structure where semiconductor devices including silicon materials and recording materials such as phase change materials or ReRAM materials are stacked, comprising:
(1) depositing the recording materials on a semiconductor substrate;
(2) depositing a metal film to cover an entire surface of the semiconductor substrate on which the recording materials are deposited;
(3) depositing an amorphous silicon forming the semiconductor device on the metal film; and
(4) crystallizing the amorphous silicon by annealing in a short time.

2. The method of manufacturing a semiconductor memory device according to claim 1, wherein as the metal film deposited at step (2), a stacked film of W, W and Ti, Ni, or Co is deposited.

3. The method of manufacturing a semiconductor memory device according to claim 1, further comprising:
prior to step (4), forming a first conductive type impurity region in one of an upper region that is located on a surface side of the amorphous silicon and a lower region that is located on the metal film side; and
forming a second conductive type impurity region in the other of the upper region and the lower region.

4. The method of manufacturing a semiconductor memory device according to claim 3, wherein any one or both of the first conductive type impurity region and the second conductive type impurity region are formed by ion implantation.

5. The method of manufacturing a semiconductor memory device according to claim 4, wherein after the amorphous silicon including the first conductive type impurity region is deposited, the second conductive type impurity region is formed by ion implantation.

6. The method of manufacturing a semiconductor memory device according to claim 4, wherein after the amorphous silicon including the first conductive type impurity region is deposited and a second amorphous silicon is deposited on the amorphous silicon including the first conductive type impurity region, the second conductive type impurity region is formed by ion implantation.

7. The method of manufacturing a semiconductor memory device according to claim 6, further comprising:
after the amorphous silicon including the first conductive type impurity region is deposited, crystallizing the amorphous silicon including the first conductive type impurity region by annealing in a short time; and
after the second amorphous silicon is deposited on the silicon including the crystallized first conductive type impurity region, forming the second conductive type impurity region by ion implantation.

8. The method of manufacturing a semiconductor memory device according to claim 1, further comprising:
prior to step (4), forming a first conductive type high-concentration impurity region in one of the upper region that is located on a surface side of the amorphous silicon and the lower region that is located on the metal film side; and
forming a first conductive type low-concentration impurity region in the other of the upper region and the lower region.

9. The method of manufacturing a semiconductor memory device according to claim 1, wherein when forming a memory having a structure in a pillar shape where the recording material and the semiconductor device are stacked,
at step (2), before the entire surface of the semiconductor substrate is covered with the metal film, the recording material is patterned in a stripe shape or a dot shape by using a minimum dimension when the structure in the pillar shape is processed.

10. The method of manufacturing a semiconductor memory device according to claim 1, wherein at step (4) before the amorphous silicon is crystallized, patterning is performed so that the metal film formed at step (2) is left in a portion where the semiconductor devices are stacked.

11. The method of manufacturing a semiconductor memory device according to claim 9, further comprising burying an insulating film in a space between the recording materials that are patterned in the stripe shape or the dot shape.

12. A method of manufacturing a semiconductor memory device having a structure where an array of a memory cell including silicon materials forming semiconductor devices and a recording material such as a phase change material or an ReRAM material are stacked, comprising:
(A) depositing the recording materials on a semiconductor substrate;
(B) depositing an insulating film to cover an entire surface of the semiconductor substrate on which the recording materials are deposited;
(C) depositing the metal film to cover an entire surface of the insulating film;
(D) depositing an amorphous silicon forming a diode on the metal film; and
(E) crystallizing the amorphous silicon by annealing in a short time.

13. The method of manufacturing a semiconductor memory device according to claim 12, further comprising:
at step (D), forming a first conductive type impurity region in one of an upper region that is located on a surface side of the amorphous silicon and a lower region that is located on the metal film side; and
forming a second conductive type impurity region in the other of the upper region and the lower region.

14. The method of manufacturing a semiconductor memory device according to claim 13, wherein any one or both of the first conductive type impurity region and the second conductive type impurity region are formed by ion implantation.

15. The method of manufacturing a semiconductor memory device according to claim 13, wherein after the amorphous silicon including the first conductive type impurity region is deposited, the second conductive type impurity region is formed by ion implantation.

16. The method of manufacturing a semiconductor memory device according to claim 12, further comprising:
at step (D), forming a first conductive type high-concentration impurity region in one of the upper region that is located on a surface side of the amorphous silicon and the lower region that is located on the metal film side; and
forming a first conductive type low-concentration impurity region in the other of the upper region and the lower region.

17. The method of manufacturing a semiconductor memory device according to claim 12, wherein when forming a memory having a structure in a pillar shape where the recording material and the semiconductor device are stacked,
at step (B), before the entire surface of the semiconductor substrate is covered with the insulating film, the recording material of step (A) is patterned in a stripe shape or a dot shape by using a minimum dimension when the structure in the pillar shape is processed.

18. The method of manufacturing a semiconductor memory device according to claim 17, further comprising burying an insulating film in a space between the recording materials that are patterned in the stripe shape or the dot shape.

19. A semiconductor memory device comprising:
an insulating film that is formed on a semiconductor substrate;
a plurality of first metal lines that are formed on the insulating film;
a plurality of diodes that are formed on each of the plurality of first metal lines;
first electrodes that are formed on each of the plurality of diodes;
recording materials such as phase change materials or ReRAM materials that are formed on the first electrodes;
second electrodes that are formed on the phase change materials; and
a plurality of second metal lines that are formed the second electrodes,
wherein the first metal line is made of metal having thermal conductivity higher than that of the second electrode interposed between the recording material and the second metal line.

20. The semiconductor memory device according to claim 19, wherein the first electrode and the second electrode are made of metal having thermal conductivity lower than that of the first metal line and the second metal line.
